(19) United States
(12) Patent Application Publication
(10) Pub. No.: US 2025/0157813 A1
(43) Pub. Date: May 15, 2025

(54) Semiconductor Device and Method of Forming Silicon Carbide Switch-Back Engineered Substrate

(71) Applicant: IceMos Technology Limited, Belfast (GB)

(72) Inventors: Samuel J. Anderson, Tempe, AZ (US); Takeshi Ishiguro, Fukushima (JP); Cathal Duffy, Belfast (GB)

(73) Assignee: IceMos Technology Limited, Belfast (GB)

(21) Appl. No.: 18/945,187

(22) Filed: Nov. 12, 2024

Related U.S. Application Data
(60) Provisional application No. 63/598,402, filed on Nov. 13, 2023.

(51) Int. Cl. H01L 21/02; H01L 21/04; H01L 21/18; H01L 29/04; H01L 29/16; H01L 29/165

(52) U.S. Cl. CPC H01L 21/02529; H01L 21/0475; H01L 21/187; H10D 62/40; H10D 62/822; H10D 62/8325

(57) ABSTRACT

A semiconductor device has a first substrate and a first semiconductor layer formed over the first substrate. A second substrate is disposed over a surface of the first semiconductor layer opposite the first substrate. The first semiconductor layer and second semiconductor layer can be silicon carbide or cubic silicon carbide. The first substrate and a portion of the first semiconductor layer are removed to reduce defects in the first semiconductor layer. A second semiconductor layer is formed over a remaining portion of the first semiconductor layer. A third semiconductor layer is disposed over the second semiconductor layer. The third semiconductor layer can be silicon. The third semiconductor layer can be disposed over the second semiconductor layer by direct wafer bonding. An electrical component is formed within the third semiconductor layer. The electrical component can be a power MOSFET, IGBT, CTIGBT, diode, and thyristor.

### CLAIM TO DOMESTIC PRIORITY

The present application claims the benefit of U.S. Provisional Application No. 63/598,402, filed Nov. 13, 2023, which application is incorporated herein by reference.

### FIELD OF THE INVENTION

The present invention relates in general to a semiconductor device and, more particularly, to a semiconductor device and method of forming a substantially defect-free silicon carbide switch-back engineered substrate.

### BACKGROUND OF THE INVENTION

Semiconductor devices are commonly found in modern electrical products. Semiconductor devices vary in the number and density of electrical components. Discrete semiconductor devices generally contain one type of electrical component, e.g., a light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, interface circuits, and other signal processing circuits.

Semiconductor devices perform a wide range of functions, such as signal processing, high-speed calculations, transmitting and receiving electromagnetic signals, controlling electrical devices, transforming sunlight to electricity, and creating visual projections for television displays. Semiconductor devices are found in the fields of communications, power conversion, networks, computers, and consumer products. Semiconductor devices are also found in military applications, aerospace, aviation, automotive, data processing centers, industrial controllers, and office equipment.

MOSFETs are commonly used in electrical circuits, such as communication systems and power supplies. Power MOSFETs are particularly useful when used as electric switches to enable and disable the conduction of relatively large currents. The on/off state of the power MOSFET is controlled by applying and removing a triggering signal at the gate electrode. When turned on, the electric current in the MOSFET flows between the drain and source. When turned off, the electric current is blocked by the MOSFET.

Power MOSFETs are typically arranged in an array of thousands of individual MOSFET cells electrically connected in parallel. The power MOSFET cell has an inherent drain-source resistance (R_{DSON}) in the conducting state. The width of the power MOSFET cell influences the electrical resistance of the power MOSFET cell. The larger the cell width, the larger the resistance. Conversely, the larger the cell density with corresponding smaller cell width, the smaller the resistance. Many applications, such as portable electrical devices, require a low operating voltage, e.g., less than 5 VDC. The low voltage electrical equipment in the portable electrical devices creates a demand for power supplies that can deliver the requisite operating potential.

With respect to the power MOSFET, such devices have been made with a super-junction structure. Advances have been made to merge micro-electrical-mechanical system (MEMS) layer transfer and super-junction technology. Super-junction has been an important development for power devices since the introduction of the insulated gate bipolar transistor (IGBT) in the 1980s. Super-junction has extended the well-known theoretical study on the limit of silicon in high-voltage devices. MEMS super-junction reduces manufacturing cost by merging MEMS processing techniques into CMOS processes to build super-junction metal oxide semiconductor (SJMOS) structures.

Super-junction can be challenging to realize in practice, due to the requirement of forming three-dimensional device structures with a high aspect ratio. SJMOS addresses the super-junction manufacturing and cost problem through a low-cost, commercially viable MEMS layer transfer and deep reactive ion etch fabrication technology. The comparison between multiple-epi and the merger of MEMS based SJMOS devices is differentiated by the number of mask layers. There can be twenty or more mask layers used in the manufacture of multi-epi, while SJMOS uses nine mask layers.

Many semiconductor devices use a substrate made at least in part with silicon carbide (Sic) semiconductor material, such as 4H and 6H SiC. The SiC semiconductor layer or substrate provides some useful advantages, such as high breakdown voltage, high speed, reduced switching losses, high power density, high temperature, better heat dissipation, and increased bandwidth capability. For example, an anneal for 4H or 6H SiC may reach 1700° C. However, forming the SiC layer on a Si layer produces a heterointerface between two dissimilar materials with different lattice structures and different coefficients of thermal expansion (CTE). The heterointerface causes stress during temperature cycling and leads to defects in the SiC layer, including triangle defects, carrot defects, surface pits, step bunching, micro-twins, stacking faults, basal plane dislocations (BPD), micropipes (MP), threading screw dislocations (TSD), and threading edge dislocations (TED). Many attempts have been made to reduce the defect density in the SiC substrate. For example, attempts have been made to accurately control surface chemistry during the epitaxial growth. In other examples, attempts have been made to optimize etch time prior to epitaxy, to optimize the shape of the wafers via optimized crystal growth, wafering, and polishing processes, and to make use of buffer-layers, high temperature processes, intrinsic strain reduction, and patterned Si-substrates when growing SiC or 3C—SiC heteroepitaxy. The work done to date has focused on reducing defects in the SiC substrate, which has only served to increase manufacturing costs, while continuing to produce SiC substrates with high defect densities and low yield.

### BRIEF DESCRIPTION OF THE DRAWINGS

FIG. 1 illustrates a block diagram of a power supply and electrical equipment;

FIG. 2 is a schematic and block diagram of a pulse width modulated power supply;

FIG. 3 illustrates a semiconductor wafer with a plurality of semiconductor die;

FIGS. 4a-4n illustrate a process of forming a substantially defect-free silicon carbide switch-back engineered substrate;

FIGS. 5a-5k illustrate a process of forming a high-breakdown voltage power MOSFET cell within the substantially defect-free silicon carbide switch-back engineered substrate;

FIG. 6 illustrates a high-breakdown voltage trench gate power MOSFET formed within the substantially defect-free silicon carbide switch-back engineered substrate;

FIGS. 7a-7o illustrate another process of forming a high-breakdown voltage power MOSFET cell within the substantially defect-free silicon carbide switch-back engineered substrate using vapor phase deposition;

FIG. 8 is a top view of the multi-cell power MOSFET formed within the substantially defect-free silicon carbide switch-back engineered substrate;

FIGS. 9a-9h illustrate another process of forming a high-breakdown voltage power MOSFET cell within the substantially defect-free silicon carbide switch-back engineered substrate using vapor phase deposition;

FIGS. 10a-10g illustrate a process of forming a high-breakdown voltage power MOSFET cell within the substantially defect-free silicon carbide switch-back engineered substrate using epi doping; and

FIGS. 11a-11e illustrate an atomic level deposition of p dopant to form the epi doping.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Most modern electrical equipment requires a power supply to provide a DC operating potential to the electrical components contained therein. Common types of electrical equipment which use power supplies include aerospace, personal computers, energy systems, telecommunication systems, audio-video equipment, consumer electrical devices, automotive components, portable electrical devices, data processing centers, LED lighting, electric vehicles, and other devices which utilize integrated circuits, semiconductor chips, or otherwise require DC operating potential. Many semiconductor components require a low voltage DC operating potential. However, many sources of electric power are AC, or high voltage DC, which must be converted to low voltage DC for the electrical equipment.

In one common arrangement, the AC/DC power supply receives an AC input voltage, e.g., between 110 and 240 VAC, and converts the AC input voltage to the DC operating voltage. Referring to FIG. 1, a PWM power supply 30 is shown providing a DC operating potential to electrical equipment 32. Power supply 30 receives input voltage V_{IN} and produces one or more DC output voltages. The electrical equipment 32 may take the form of aerospace equipment, personal computers, energy systems, telecommunication systems, audio-video equipment, consumer electrical devices, automotive components, portable electrical devices, aerospace, data processing centers, LED lighting, charging stations for electric vehicles, variable speed drives for electric motors, and other devices which utilize integrated circuits, semiconductor chips, or otherwise require DC operating potential from the power supply.

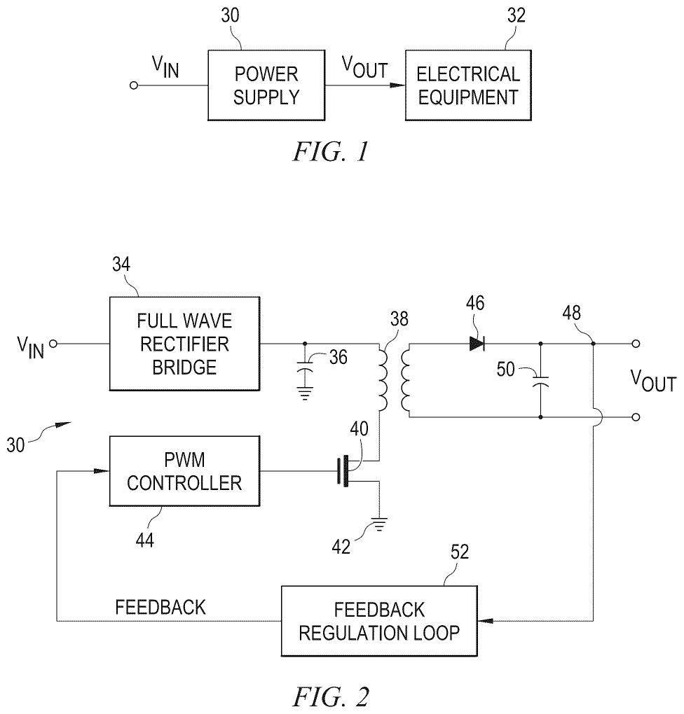

Further detail of PWM power supply 30 is shown in FIG. 2. The input voltage V_{IN} may be an AC signal, e.g., 110 VAC, or DC signal, e.g., 48 volts. For the case of an AC input voltage, power supply 30 has a full-wave rectifier bridge 34. The full-wave rectifier bridge 34 converts the AC input voltage to a DC voltage. In the case of a DC input voltage, the full-wave rectifier bridge 34 is omitted. Capacitor 36 smooths and filters the DC voltage. The DC voltage is applied to a primary winding or inductor of transformer 38. The primary winding of transformer 38 is also coupled through power transistor 40 to ground terminal 42. In one embodiment, power transistor 40 is a multi-cell vertical power MOSFET, as described in subsequent figures. The gate of power MOSFET 40 receives a PWM control signal from PWM controller 44. The secondary winding of transformer 38 is coupled to rectifier diode 46 to create the DC output voltage V_{OUT} of power supply 30 at node 48. Capacitor 50 filters the DC output voltage V_{OUT}. The DC output voltage V_{OUT} is routed back through feedback regulation loop 52 to a control input of PWM controller 44. The DC output voltage V_{OUT} generates the feedback signal which PWM controller 44 uses to regulate the power conversion process and maintain a relatively constant output voltage V_{OUT} under changing loads. The aforedescribed electrical components of the power supply module are typically mounted to and electrically interconnected through a printed circuit board.

In the power conversion process, PWM controller 44 sets the conduction time duty cycle of power MOSFET 40 to store energy in the primary winding of transformer 38 and then transfer the stored energy to the secondary winding during the off-time of power MOSFET 40. The output voltage V_{OUT} is determined by the energy transfer between the primary winding and secondary winding of transformer 38. The energy transfer is regulated by PWM controller 44 via the duty cycle of the PWM control signal to power MOSFET 40. Feedback regulation loop 52 generates the feedback signal to PWM controller 44 in response to the output voltage V_{OUT} to set the conduction time duty cycle of power MOSFET 40.

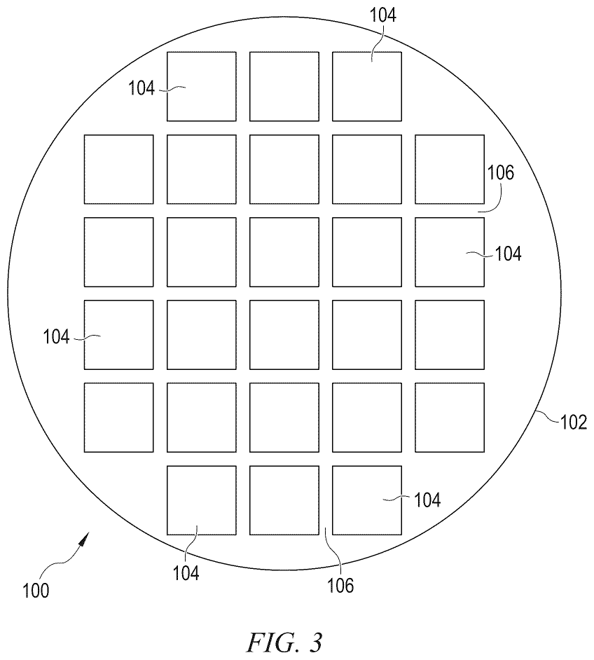

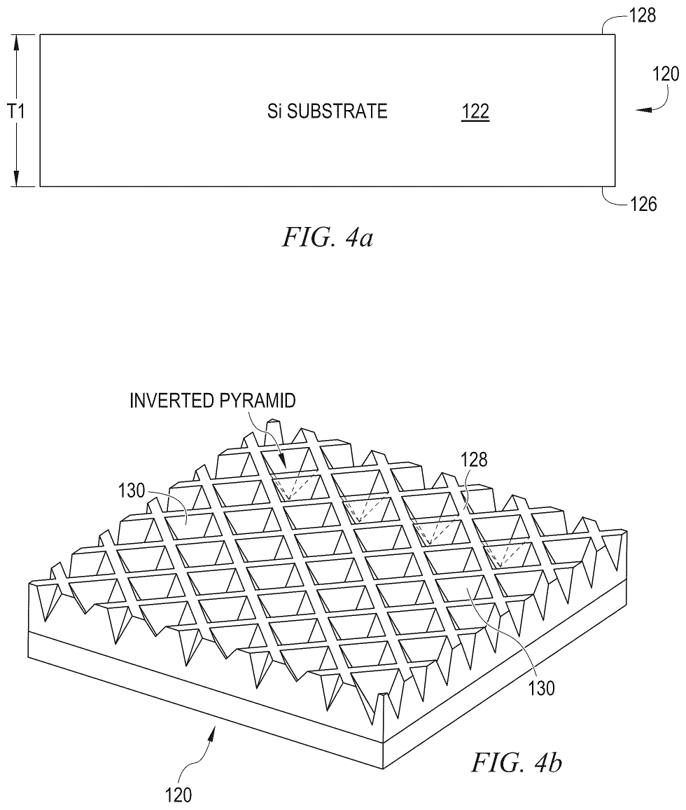

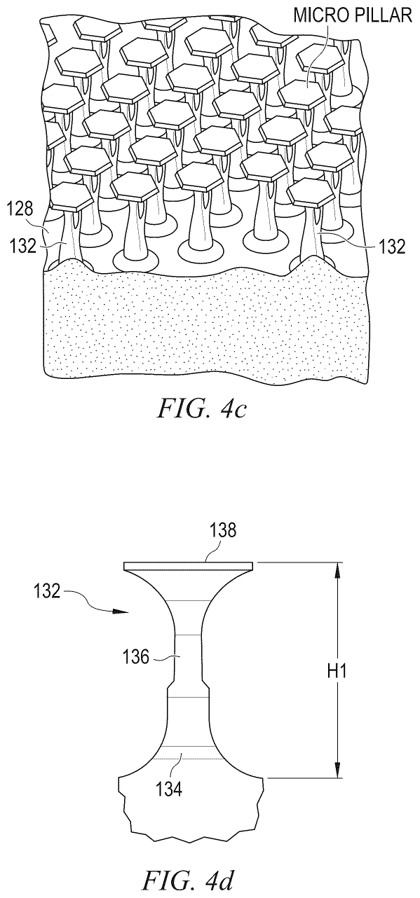

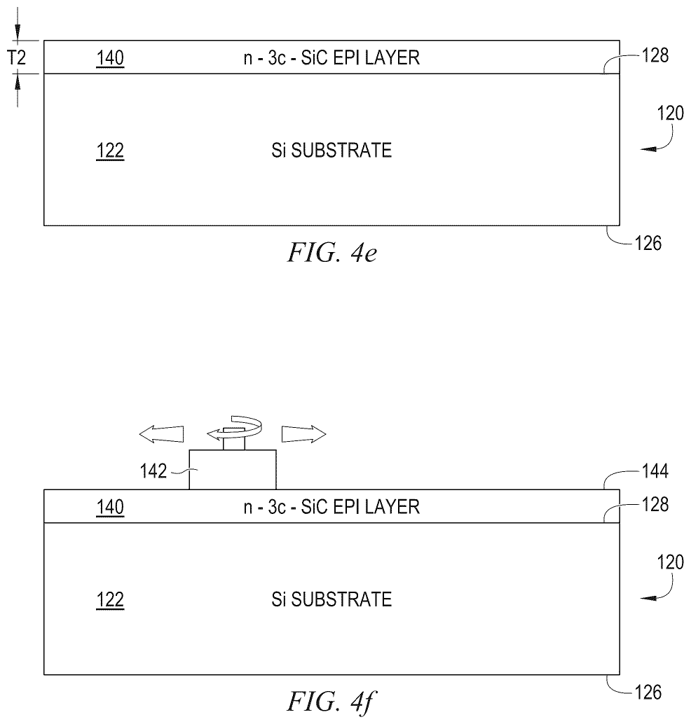

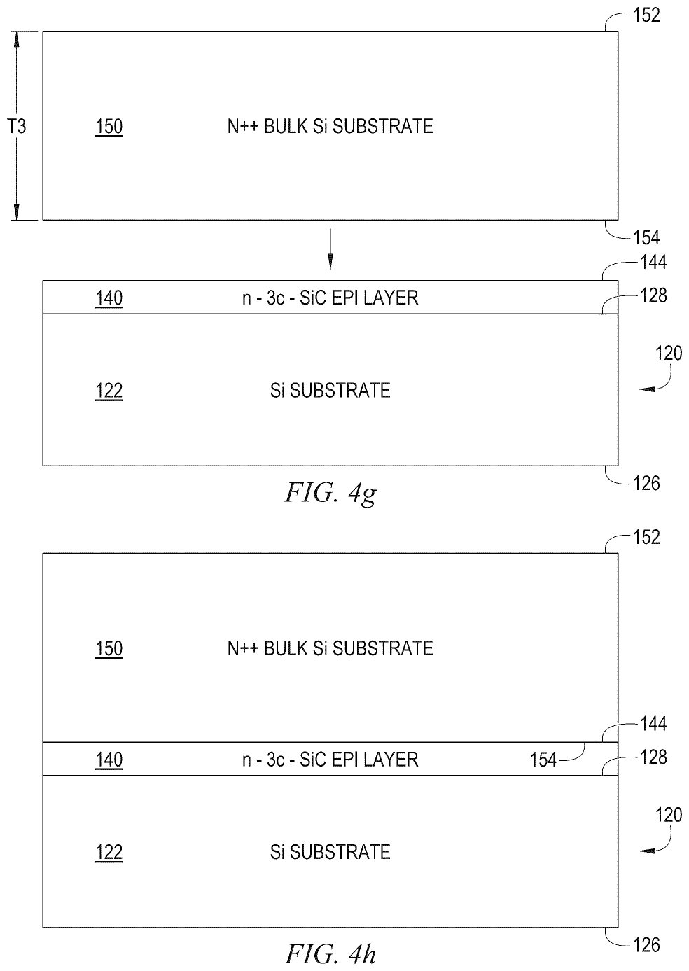

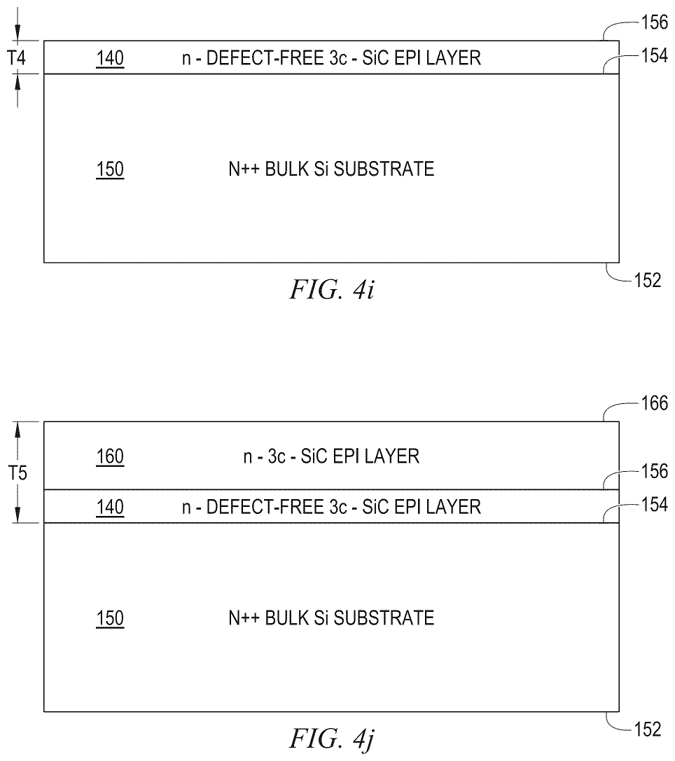

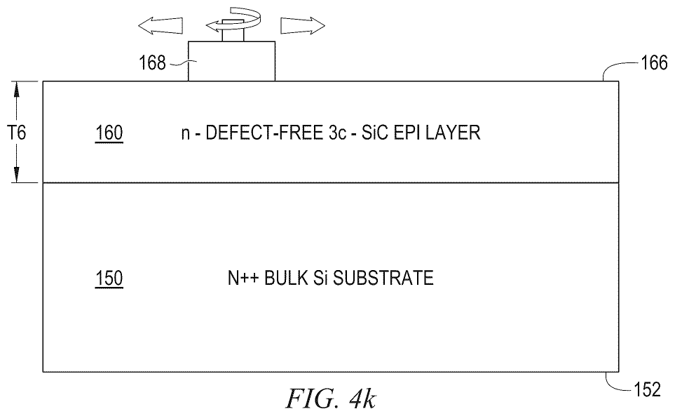

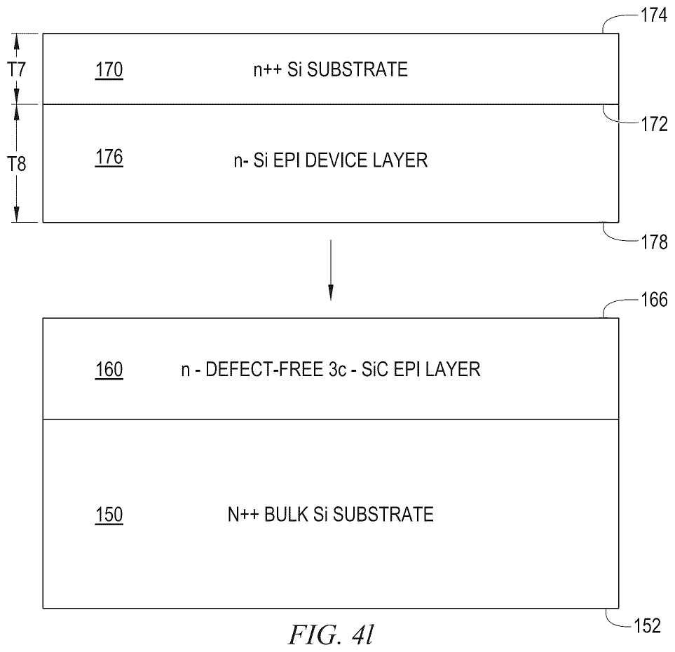

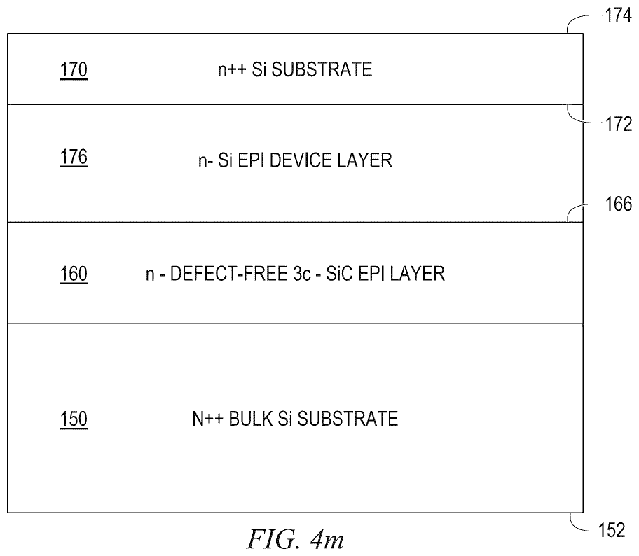

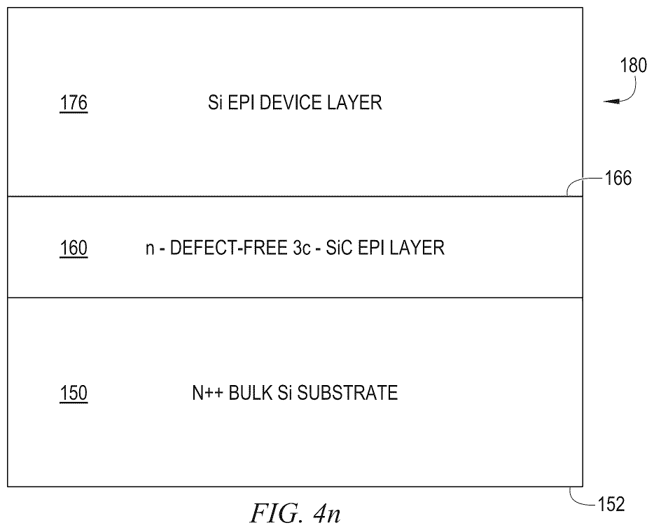

FIG. 3 shows semiconductor wafer or substrate 100 with a base substrate material 102, such as silicon (Si), SiC, cubic silicon carbide (3C—SiC), germanium, aluminum phosphide, aluminum arsenide, gallium arsenide, gallium nitride, indium phosphide, diamond, and all families of III-V and II-VI semiconductor materials for structural support. In one embodiment, substrate 100 includes a nearly or substantially defect-free SiC substrate, as described in FIGS. 4a-4n. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

Semiconductor die 104 can be a vertical or lateral power MOSFET with gate and source terminals on a first surface of the die and drain terminal on a second surface opposite the first surface of the die. Semiconductor die 104 can be contained in a semiconductor package, such as TO220, T0247, decawat package (DPAK), double decawat package (D2PAK), TSON, micro leadframe package (MLP), dual flat no-leads (DEN), and other packages for vertical discrete devices or lateral chip scale up-drain packages.

FIGS. 4a-4n illustrate a process of forming a substantially defect-free silicon carbide switch-back engineered substrate. FIG. 4a illustrates substrate 120 containing a base semiconductor material 122, such as Si, SiC, 3C—SiC, germanium, aluminum phosphide, aluminum arsenide, gallium arsenide, gallium nitride, indium phosphide, diamond, and all families of III-V and II-VI semiconductor materials for structural support. In one embodiment, substrate 120 contains bulk Si with a thickness T1 of about 625 micrometers (μm) and diameter or width of 100-450 mm. Substrate 120 includes a first major surface 126 and second major surface 128 opposite the first major surface 126.

Substrate 120 is a sacrificial, inverted pyramid patterned, compliant, bulk Si substrate. Substrate 120 operates as a sacrificial handle as it will later be removed. In one embodiment, surface 128 of substrate 120 is an inverted pyramid patterned, textured surface, as shown in FIG. 4b. Small inverted pyramid-shaped voids 130 are patterned and etched into surface 128 to create structured substrate 120. Alternatively, surface 128 of substrate 120 is an unpatterned planar surface.

The structured substrate 120 comes from the consideration that the stacking faults (SF) lie on (111) planes and can interact with each other, stopping the propagation. With two SFs laying, for example, in the (111) and (11-1) planes, the SFs can cross, and the structure is able to stop the propagation of one or even both SFs to improve the crystalline quality of the film surface because the SFs remain buried in the epi-layer. The rate of SF annihilation is inversely related to SF density, however, by means of the inverted pyramid pattern, allowing for a significant drop in SF concentration just within a few microns from the heterointerface allows that defect density to decrease with increasing epitaxial layer thickness. The unique pyramid shape can concentrate SFs in small areas, enhancing the phenomenon of SF annihilation.

In another embodiment, as shown in FIG. 4c, a plurality of micropillars 132 is patterned and formed into hexagonal arrays on surface 128 of structured substrate 120 by a dry etching process. Micropillars 132 can be made with Si. FIG. 4d illustrates one micropillar 132 with base 134, stem 136, and pedestal 138. The height H1 of micropillar 132 is about 9.35 μm. Pedestal 138 of one micropillar 132 may contact another pedestal of an adjacent micropillar. The compliant structured substrate 120 with micropillars 132 releases the stress developed in 3C—SiC grown on Si substrate, due to the lattice mismatch and the different CTE between 3C—SiC and Si.

In FIG. 4e, semiconductor layer 140 is epitaxially grown over surface 128 of structured substrate 120. In one embodiment, semiconductor epi layer 140 is formed using hot wall CVD and then implanted with n-type dopant, e.g., phosphorus at 1e14 to 1e16 atoms/cm³, to form an N—SiC epi layer or N-3C—SiC epi layer with a thickness T2 of 3.0 μm. In another embodiment, thickness T2 can range from 3.0-30.0 μm.

Of particular relevance is that the contact between semiconductor material 122 (Si) and semiconductor layer 140 (SiC or 3C—SiC) involves a heterointerface between two dissimilar materials with different lattice structures and different CTE. The growth of the SiC or 3C—SiC semiconductor layer 140 over the structured Si substrate 120, cycling over a temperature range, creates stress and strain at the hetero-boundary around surface 128, which results in defects in or around the interface regions. The density of defects can be significant at the interface region proximate to surface 128, hence semiconductor layer 140 is characterized as having a high defect density near surface 128. Small inverted pyramid-shaped voids 130, or micropillars 132, formed in surface 128, as described in FIGS. 4b-4d, operate to self-annihilate or otherwise relieve the stress and associated expansion of defects. The stress and strain inherent to heteroepitaxy growth can reside in, and are substantially limited to, portions of structured substrate 120 and semiconductor layer 140 proximate to surface 128 due to the annihilation effect from the inverted pyramid-shaped voids 130, or micropillars 132, as formed in surface 128. Defects are confined to about 1.0-1.5 μm from surface 128 into semiconductor layer 140 and about 3.0-6.0 μm from surface 128 into semiconductor material 122. The annihilation effect increases with greater thickness of semiconductor epi layer 140. The remaining SiC or 3C—SiC semiconductor layer 140 is substantially defect-free, or at least the lowest defect density portion of semiconductor layer 140, because the defects substantially occur in and are confined to the areas proximate to surface 128.

In FIG. 4f, surface 144 of semiconductor layer 140 undergoes a chemical mechanical polish (CMP) with grinder 142 to prepare for bonding. The CMP reduces the thickness of semiconductor layer 140 to about 2.7 μm.

In FIG. 4g, N++ bulk Si substrate 150 is disposed over surface 144 for bonding to semiconductor layer 140. In one embodiment, substrate 150 contains N++ bulk Si with a thickness T3 of about 625 μm and diameter or width of 100-450 mm. In one embodiment, surface 154 of N++ bulk Si substrate 150 has an inverted pyramid patterned, textured surface, or a plurality of micropillars 132, similar to surface 128 of substrate 120 in FIG. 4b-4d. Alternatively, surface 154 of substrate 150 is an unpatterned planar surface.

Structured substrate 150 is joined to semiconductor layer 140 using a high temperature anneal, fusion bonding, plasma activated direct wafer bonding (DWB), or other DWB process. Surface 144 of semiconductor layer 140 and surface 154 of structured substrate 150 are planarized, polished, and cleaned to be flat and smooth, prior to bonding. The lattice structures of semiconductor layer 140 and structured substrate 150 can be aligned to optimize adhesion. Water molecules can be applied to surfaces 144 and 154 to aid in the bonding process. Surface 154 of structured substrate 150 is brought into contact with surface 144 of semiconductor layer 140. DWB is accomplished with chemical bonds and intermolecular interactions at temperature, including van der Waals forces, hydrogen bonds, and covalent bonds, between surface 144 and surface 154. DWB temperatures range from ambient to 100's° C. FIG. 4h shows structured substrate 150 direct wafer bonded to surface 144 of semiconductor layer 140.

In another embodiment, semiconductor layer 140 is direct wafer bonded to surface 128 of structured substrate 120, similar to FIGS. 4g-4h.

In FIG. 4i, the assembly from FIG. 4h is inverted and structured substrate 120 and the high defect density portion of semiconductor layer 140 are removed, leaving substrate 150 and the remaining substantially defect-free portion semiconductor layer 140. Removing all of the structured substrate 120 and about 1.7 μm of semiconductor layer 140 removes a substantial portion of the defects. The remaining substantially defect-free portion of semiconductor layer 140, or at least the lowest defect density portion of semiconductor layer 140, proximate to surface 154 of substrate 150, has thickness T4 of about 1.0 μm. The remaining substantially defect-free portion of semiconductor layer 140 operates as a seed layer for the next level of processing. The inversion of the assembly from FIG. 4h and removal of structured substrate 120 and the high defect density portion of semiconductor layer 140 is referred to as providing a switch-back defect-free substrate.

In FIG. 4j, semiconductor layer 160 is epitaxially grown over surface 156 of semiconductor layer 140, i.e., the seed layer, using hot wall CVD. In one embodiment, semiconductor layer 160 is implanted with n-type dopant, e.g., phosphorus at 1e14 to 1e16 atoms/cm³, to form an N—SiC epi or N-3C—SiC epi layer with a thickness T5 of 10.3 μm. In another embodiment, N—SiC epi or N-3C—SiC epi layer 160 can have a thickness T5 of 5.3-30.3 μm. Since the formation of semiconductor layer 160 over semiconductor layer 140 effectively merges the two layers, FIGS. 4k-4n omit seed semiconductor layer 140 and show only the resulting semiconductor layer 160. Further, given the small inverted pyramid-shaped voids 130 and/or micropillars 132 formed in surface 154 of structured substrate 150, the annihilation effect described above continues for semiconductor layer 160 providing a substantially defect-free semiconductor epi layer 160. In particular, surface 166 of semiconductor layer 160 is considered substantially defect free.

In a similar process as FIGS. 4g-4h, semiconductor layer 160 could have been direct wafer bonded to surface 156 of semiconductor layer 140, still effectively merging the two layers, as shown in FIGS. 4k-4n. In another embodiment, semiconductor layer 160 is direct wafer bonded to surface 156 of semiconductor layer 140, similar to FIGS. 4g-4h.

In FIG. 4k, surface 166 of semiconductor layer 160 undergoes CMP with grinder 168 to prepare for bonding. The CMP reduces the thickness T6 of semiconductor layer 160 to about 10.0 μm. In another embodiment, semiconductor layer 160 can have a post-grinding thickness of 5.0-30.0 μm.

FIG. 4l shows N++Si substrate 170 containing a base semiconductor material, such as Si, SiC, 3C—SiC, germanium, aluminum phosphide, aluminum arsenide, gallium arsenide, gallium nitride, indium phosphide, diamond, and all families of III-V and II-VI semiconductor materials for structural support. In one embodiment, substrate 170 contains bulk Si with a thickness T7 of about 575 μm. Substrate 170 includes a first major surface 172 and second major surface 174 opposite the first major surface 172. Substrate 170 operates as a sacrificial handle as it will later be removed.

Semiconductor layer 176 is epitaxially grown over surface 172 of substrate 170. In one embodiment, semiconductor epi layer 176 is formed using hot wall CVD and then implanted with n-type dopant, e.g., phosphorus at 1e14 to 1e16 atoms/cm³, to form an N—Si epi layer with a thickness T8 of 65.0 μm. The thickness of semiconductor epi layer 176 is proportional to breakdown voltage. This thickness is actually reduced during Si substrate 170 removal, thus 65.0 μm thickness is slightly larger than the target thickness for 600V. Alternatively, semiconductor layer 176 is direct wafer bonded to surface 172 of substrate 170, similar to FIGS. 4g-4h.

Semiconductor layer 176, supported by substrate 170, is disposed over surface 166 of semiconductor layer 160. Semiconductor layer 176 is joined to semiconductor layer 160 using a high temperature anneal, fusion bonding, plasma activated DWB, or other DWB process. Surface 166 of semiconductor layer 160 and surface 178 of semiconductor layer 176 are planarized, polished, and cleaned to be flat and smooth, prior to bonding. The lattice structures of semiconductor layer 160 and semiconductor layer 176 can be aligned to optimize adhesion. Water molecules can be applied to surfaces 166 and 178 to aid in the bonding process. Surface 178 of semiconductor layer 176 is brought into contact with surface 166 of semiconductor layer 160. DWB is accomplished with chemical bonds and intermolecular interactions at temperature, including van der Waals forces, hydrogen bonds, and covalent bonds, between surface 166 and surface 178. DWB temperatures range from ambient to 100's° C. FIG. 4m shows semiconductor layer 176 direct wafer bonded to surface 166 of semiconductor layer 160. Surface 166 of semiconductor layer 160 is substantially oxide/defect-free SiC or 3C—SiC face to enable direct covalent bonding to Si face of surface 178 of semiconductor layer 170. The interface between semiconductor layer 170 and semiconductor layer 160 exhibits a strong bond with little or no defects in the crystalline structure.

In FIG. 4n, substrate 170 is removed, leaving SiC or 3C—SiC engineered substrate 180 with N++ bulk Si substrate 150, N-substantially defect-free semiconductor epi layer 160, and N-semiconductor epi device layer 176. The SiC or 3C—SiC engineered substrate 180, as described in FIGS. 4a-4n, can be used as a foundation to form a variety of semiconductor devices. For example, engineered substrate 180 can be used as a SiC or 3C—SiC foundation to form a high voltage power MOSFET. The innovative engineered substrate 180 allows for manufacture in a mature mode CMOS process. The switch-back process provides for low defect density on 3c-SiC or SiC epi. In addition, the Si/3C—SiC/Si structure of engineered substrate 180 is useful for radiation hardness. 3C—SiC layer provides a buffering effect over Si when a high energy particle impacts the device.

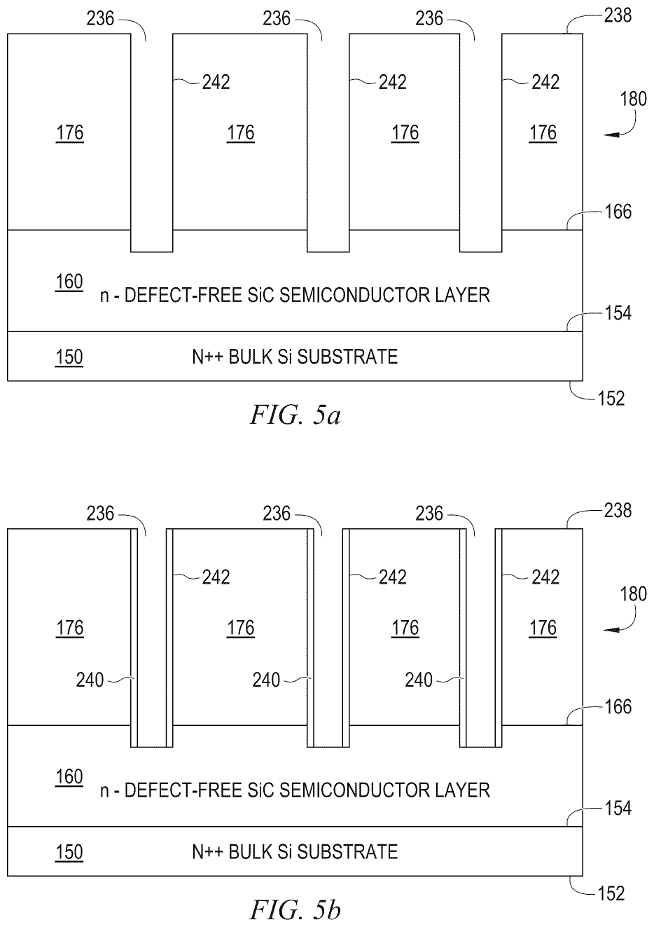

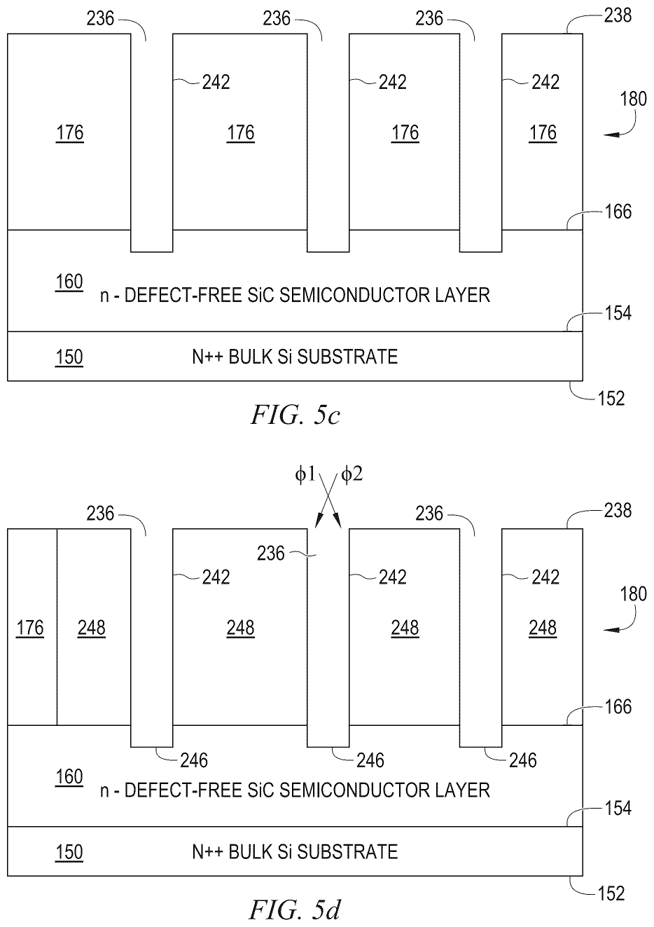

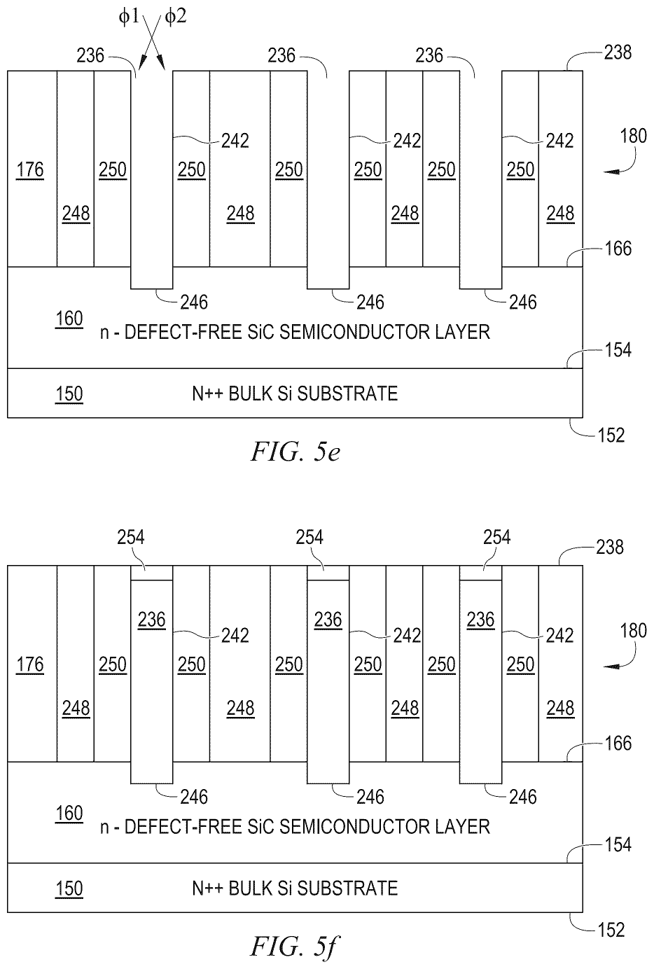

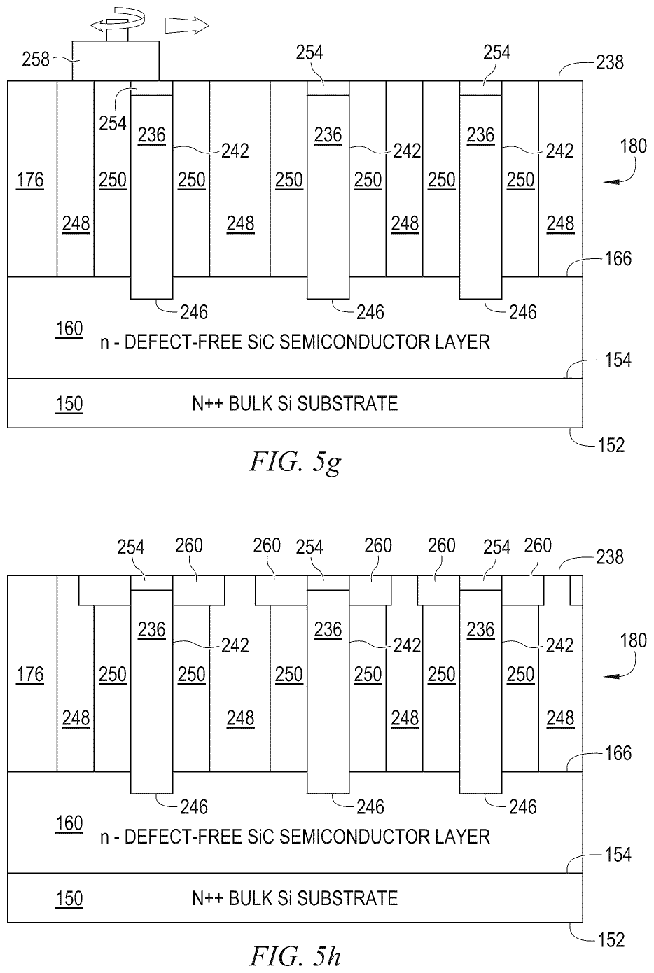

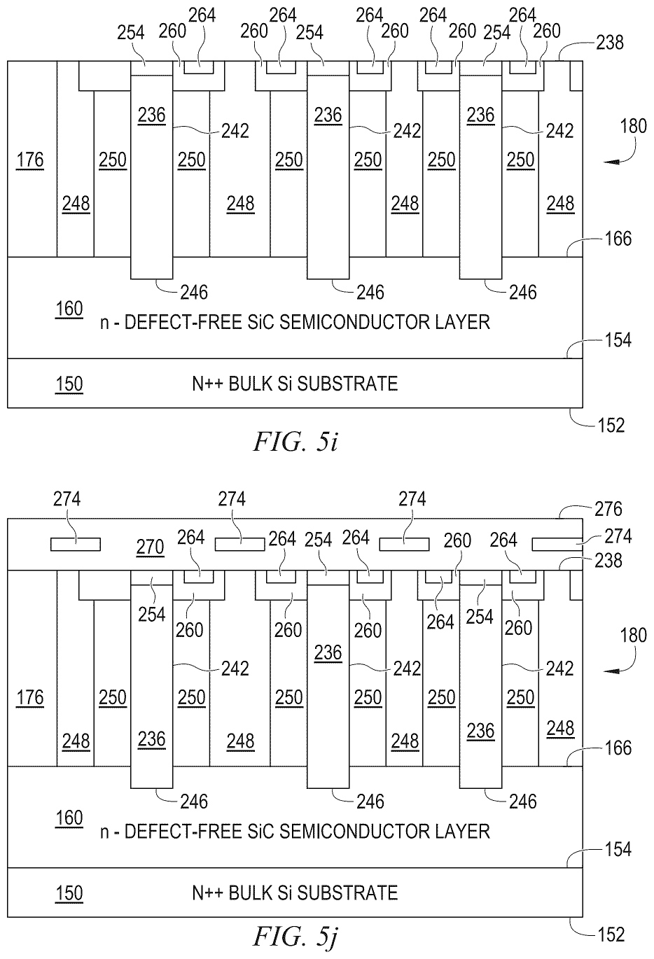

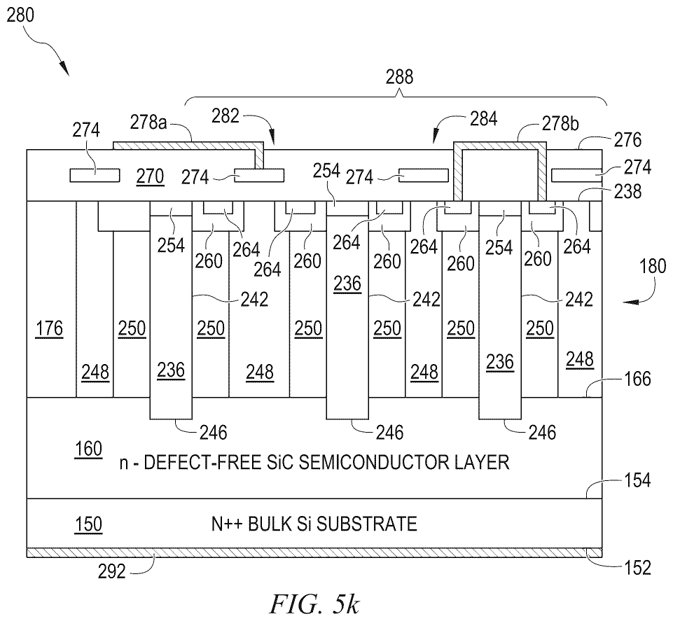

FIGS. 5a-5k illustrate a 1200 volt breakdown SJMOS with a silicon-carbide engineered drain to take advantage of the low on resistance performance from wide band gap (WBG) materials. The merger of SJMOS structures with MEMS manufacturing techniques and WBG material (collectively SMW) enables devices that, for example, can sustain 1200V blocking while delivering R_{DSON} of 90 milliohms at ID max=40 A.

Continuing from the engineered substrate 180 from FIG. 4n, trenches 236 are formed from surface 238 through semiconductor layer 176 and extending past surface 166 into defect-free SiC semiconductor layer 160, as shown in FIG. 5a. Semiconductor layer 160 can be implemented with any of the embodiments of FIGS. 4a-4n. Trenches 236 can be formed by deep reactive ion etching (DRIE) with a width of 3-6 μm and depth of 65 μm for 600 v and 115 μm for 1200 v. The DRIE is a highly anisotropic etch process used to create deep penetration, steep-sided holes, cavities, and trenches in wafers/substrates, typically with high aspect ratios. DRIE utilizes an ionized gas or plasma, such as sulfur hexafluoride (SF₆), to remove material from semiconductor layers 160 and 176. DRIE technology permits deeper trenches 236 with straighter sidewalls. To create deep anisotropic etching of silicon, the etch process switches between different plasma chemistries to provide fluorine-based etching of the silicon while protecting the sidewall of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 236. Alternatively, trenches 236 can be formed by laser direct ablation (LDA), plasma etching, reactive ion etching (RIE), sputter etching, vapor phase etching, and chemical etching. A first mask (not shown) is typically formed over surface 238 to isolate trenches 236 during the etching process.

The sidewalls 242 of each trench 236 can be smoothed using an isotropic plasma etch and may be used to remove a thin layer of silicon, e.g., 100-1000 Angstroms (A) from the trench sidewalls. Alternatively, a sacrificial thermal oxide or silicon dioxide layer 240 can be grown on sidewall surfaces 242 of trenches 236, as shown in FIG. 5b. The sacrificial thermal oxide 240 is then removed using an etch, such as a buffered oxide etch, or a diluted hydrofluoric (HF) acid etch, or other wet chemistry followed by HF vapor phase fuming, to smooth the inner wall, as shown in FIG. 5c. Another sacrificial thermal oxide layer 240 is again grown on sidewalls 242 of trenches 236, similar to FIG. 5b. The sacrificial thermal oxide layer 240 is again removed by wet chemistry followed by HF vapor phase fuming to smooth the inner wall, similar to FIG. 5c. The process of repetitive growth of thermal oxide and removal continues multiple times, in accordance with FIGS. 5b-5c, until sidewall 242 of trench 236 is smooth. By eliminating the scalloping from the DRIE etch and using sacrificial thermal oxide layer 240 followed by HF fuming or any oxide and silicon etches, sidewall 242 can be smoothed to a tapered form. The use of the smoothing techniques can produce smooth trench surfaces with rounded corners while removing residual stress and unwanted contaminates.

In FIG. 5d, sidewalls 242 of trenches 236 are implanted or doped with a dopant, which may occur at predetermined angles Φ1, Φ2. The dopant can be n-type material or p-type material, depending on the type of semiconductor device being made. Power MOSFET 280 from FIG. 5k can be an n-channel device (N-MOS) or a p-channel device (P-MOS), where “p” denotes a positive carrier type (hole) and “n” denotes a negative carrier type (electron). Although the present embodiment is described in terms of an N-MOS device, the opposite type semiconductor material can be used to form a P-MOS device.

In various implantation steps described herein, the doping is performed by ion implantation, solid diffusion, liquid diffusion, spin-on deposits, plasma doping, vapor phase doping, laser doping, or the like. Doping with boron (B), aluminum (Al), or gallium (Ga) results in a more p-type region, and doping with phosphorus (P), antimony (Sb), or arsenic (As) impurities results in n-type region 248. Other dopants may be utilized, such as bismuth (Bi) and indium (In), depending on the material of the substrate and the desired strength of the doping.

The implantation angles are determined by the width of trenches 236 and the desired doping depth and is typically from about 2° to 12° from vertical. The implant is done at angles Φ1, Φ2 so that bottom 246 of each trench 236 is not implanted. Preferably, the implantation occurs between surface 238 and surface 166 to form n region 248. The implant is performed at an energy level of about 30-200 kilo-electron-Volts (KeV) with a dose between 1e13 and 1e17 atoms/cm³. The doping preferably occurs with the aid of a mask (not shown) placed over surface 238 of semiconductor layer 176. Following implanting, a drive-in step at a temperature of up to 1200° C. may be performed for up to 12 hours. In another embodiment, there is no doping performed as region 248 is not required.

In FIG. 5e, sidewalls 242 of trenches 236 are implanted with a p-type dopant, such as boron, aluminum, or gallium impurities, with a dose of about 1e16 atoms/cm³ to form p regions 250 with a width of about 1.0 μm. Alternatively, sidewalls 242 of trenches 236 are implanted with a p-type dopant, such as boron, aluminum, or gallium impurities, with a dose of 1e14 to 1e17 atoms/cm³ to form p regions 250 with a corresponding width. The p-implant leaves columns of n region 248 and columns of p region 250. The columns of n region 248 have equal and opposite charge as the columns of p region 250. The n-type dopant and p-type dopant drive-in may occur after each implantation step, or simultaneously with the implant.

In FIG. 5f, insulating material 254 is deposited in trenches 236. In one embodiment, insulating material 254 completely fills trenches 236. Alternatively, insulating material 254 is formed over trench 236 using a MEMS layer transfer or layer bonding process to form a cap over the trench, as it is not necessary to completely fill trenches 236 with insulating material. Insulating material or cap 254 is bonded to semiconductor layer 176 to cover trench 236. Using the MEMS layer transfer process to cap trench 236, there is no need to fill the trench with any material. Insulating material 254 can be polysilicon, re-crystallized polysilicon, single crystal silicon, or semi-insulating polycrystalline silicon (SIPOS). Insulating material 254 can also be silicon dioxide (SiO2), silicon nitride (Si3N4), silicon oxynitride (SiON), tantalum pentoxide (Ta2O5), aluminum oxide (Al2O3), polyimide, benzocyclobutene (BCB), polybenzoxazoles (PBO), or other suitable insulating or dielectric material. In one embodiment, insulating material 254 is SIPOS deposited into trenches 236 using a spun-on-glass (SOG) technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

Insulating material 254 can also be deposited in trenches 236 using other techniques, such as low pressure (LP) chemical vapor deposition (CVD), tetraethylorthosilicate (TEOS), or other suitable oxide deposition process. Insulating material 254 can be deposited in trenches 236 by a reflow process. After depositing insulating material 254, surface 238 is planarized by grinder 258 or chemical-mechanical polishing (CMP), as shown in FIG. 5g.

In FIG. 5h, a p-type dopant, such as boron, aluminum, or gallium impurities, is implanted to form p body regions 260 proximate to surface 238 of semiconductor layer 176. In the case of ion implantation of the p-type dopant into n region 248 and p regions 250, one embodiment can utilize an energy level of about 30-1000 KeV with a dose of 1e17 atoms/cm³, followed by a high temperature drive-in step, e.g., a diffusion. Other implants can be deposited at appropriate dosages and energy levels. P body regions 260 can be formed at least partially by performing ion implantation of sidewalls 242 of trenches 236, prior to depositing insulating material 254 into the trenches. P body regions 260 operate as inversion layers to provide conduction channels through the semiconductor device. An oxide layer (not shown) can be formed over surface 238 as a mask for the implantation of p body regions 260, although no mask is needed for the ion implantation.

In FIG. 5i, source regions 264 are formed within p body regions 260 proximate to surface 238. Source regions 264 are heavily doped n+ type regions, formed similar to p body regions 260. The orientation of source regions 264 with respect to p body regions 260 can be varied depending upon the configuration of power MOSFET 280, see FIG. 5k.

In FIG. 5j, interlayer dielectric or insulating layer 270 and gate regions 274 are formed over surface 238 of semiconductor layer 176. Gate regions 274 can be metal, doped polysilicon, amorphous silicon, or combination thereof. In one embodiment, a first portion of insulating layer 270 is formed. Insulating layer 270 contains one or more layers of SiO2, Si3N4, SiON, Ta2O5, Al2O3, polyimide, BCB, PBO, or other suitable insulating or dielectric material. Insulating layer 270 is formed using PVD, CVD, screen printing, spin coating, spray coating, sintering, or thermal oxidation. Gate regions 274 are formed over the first portion of insulating layer 270. A second portion of interlayer dielectric or insulating layer 270 is formed over the first portion of the insulating layer and gate regions 274 to cover the gate regions. Surface 276 of insulating layer 270 can then be planarized and/or polished. In some embodiments, the first portion of insulating layer 270 can be used as a mask to form source regions 264.

In FIG. 5k, a plurality of vias is formed through insulating layer 270 to source regions 264 and gate regions 274. The vias are filled with conductive material and connect to conductive layers 278a and 278b. Conductive layers 278a and 278b can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 278a makes electrical contact to gate region 274, and conductive layer 278b makes electrical contact to source regions 264. Conductive layers 278a and 278b can be electrically isolated or electrically common depending on the configuration and operation of power 280. As a vertical device, the drain of power MOSFET 280 is provided by n region 248 (n drift region), n-type semiconductor layer 160 and 176, and N++ substrate 150. Current flow path includes conductive layer 278b, source regions 264, the channel below gate region 274, and the n-type layers to the backside drain contact 292.

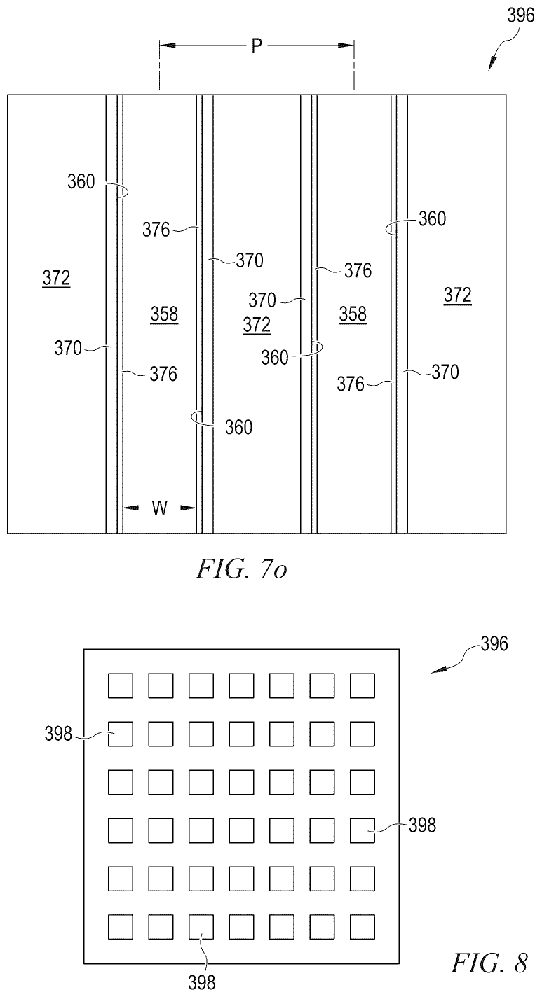

MOSFET 280 is a multi-cell vertical power MOSFET having applications in DC-DC power converters, aerospace, and general purpose portable electrical devices. FIGS. 5a-5k illustrate at least two cells 282 and 284 in active region 288. A top view of power MOSFET 280 showing multiple cells arranged in an x by y array would be similar to FIG. 8. Semiconductor layers 160 and 176 and substrate 150 represent a WBG engineered drain that enhances the device breakdown voltage to 1200V and reduces R_{DSON}. The structure of power MOSFET 280 has a feature size that is scalable to reduce cell size and provide a higher cell density, which increases the number of cells in the power MOSFET and reduces RDS_{ON} less than 5.0 mohms-cm2 at maximum drain current ID of 100.0 amperes. Power MOSFET 280 can be embodied on semiconductor die 104.

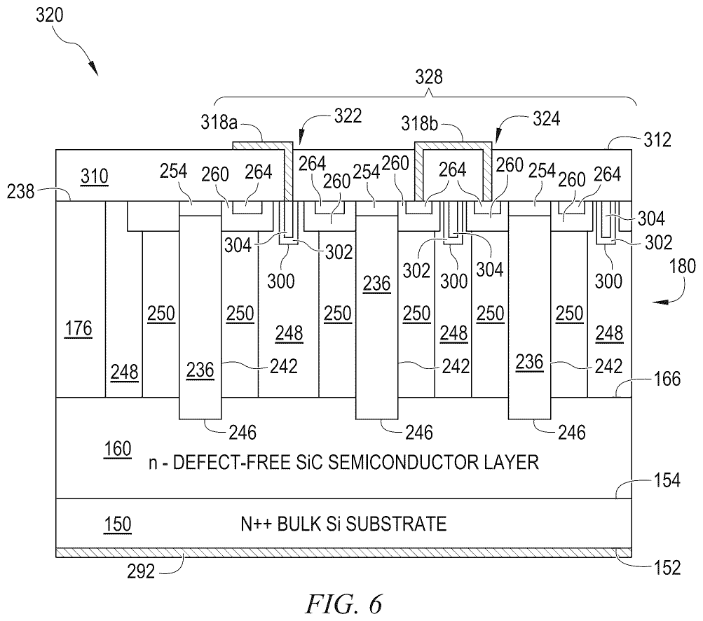

FIG. 6 illustrates an alternate embodiment of the power MOSFET with a trench gate structure. The same reference numbers are used in FIGS. 5a-5k and FIG. 6 where the function and operation are similar. Continuing from FIG. 5i, a first gate trench 300 is formed in n region 248 between p body regions 260. Gate trench 300 is filled with insulating material 302. A second gate trench is formed in insulating material 302 and filled with metal, doped polysilicon, amorphous silicon, or a combination thereof, to form gate regions 304. An interlayer dielectric or insulating layer 310 is formed over surface 238 of semiconductor layer 176. Surface 312 of insulating layer 310 can then be planarized and/or polished.

A plurality of vias is formed through insulating layer 310 to source regions 264 and gate regions 304. The vias are filled with conductive material and connect to conductive layers 318a and 318b. Conductive layers 318a and 318b can be one or more layers of W, Al, Cu, Sn, Ni, Au, Ag, or other suitable electrically conductive material formed using patterning with PVD, CVD, sputtering, electrolytic plating, electroless plating process, or other suitable metal deposition process. Conductive layer 318a makes electrical contact to gate region 304, and conductive layer 318b makes electrical contact to source regions 264. Conductive layers 318a and 318b can be electrically isolated or electrically common depending on the configuration and operation of power MOSFET 320. As a vertical device, the drain of power MOSFET 320 is provided by n region 248 (n drift region), n-type semiconductor layers 160 and 176, and N++ substrate 150. Current flow path includes conductive layer 318b, source regions 264, the channel below gate region 304, and the n-type layers to the backside drain contact 292.

MOSFET 320 is a multi-cell vertical power MOSFET having applications in DC-DC power converters, aerospace, and general purpose portable electrical devices. FIG. 6 illustrates at least two cells 322 and 324 in active region 328. Trench gate regions 304 further reduce cell size and provide a higher cell density. The power MOSFET cells are electrically connected in parallel to form a power MOSFET for high current carrying capacity, similar to FIG. 8.

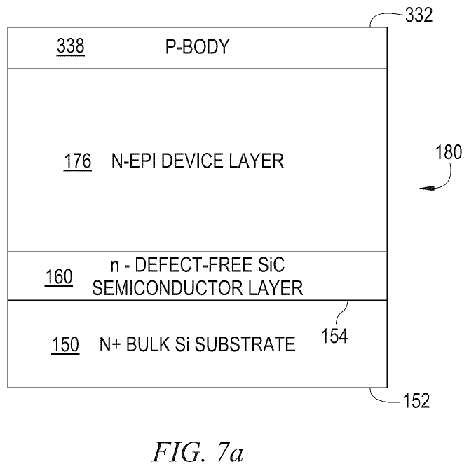

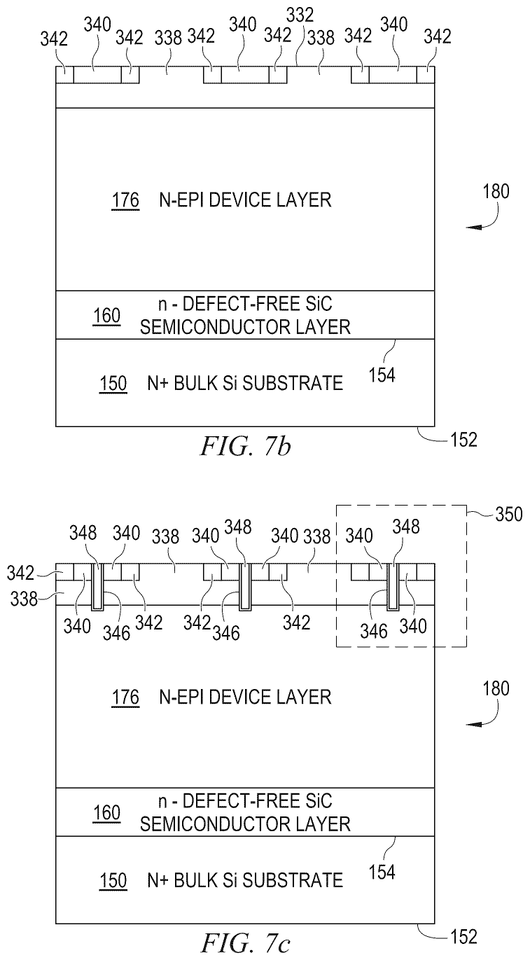

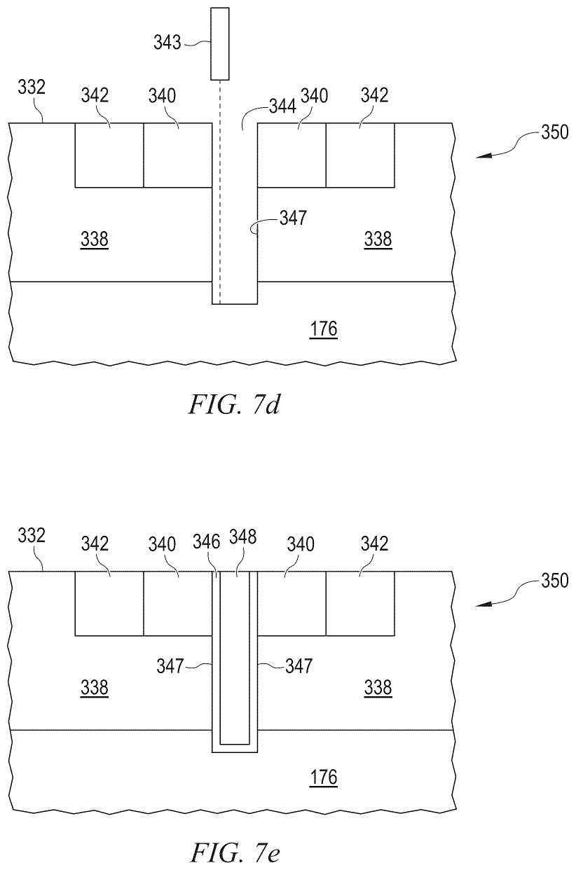

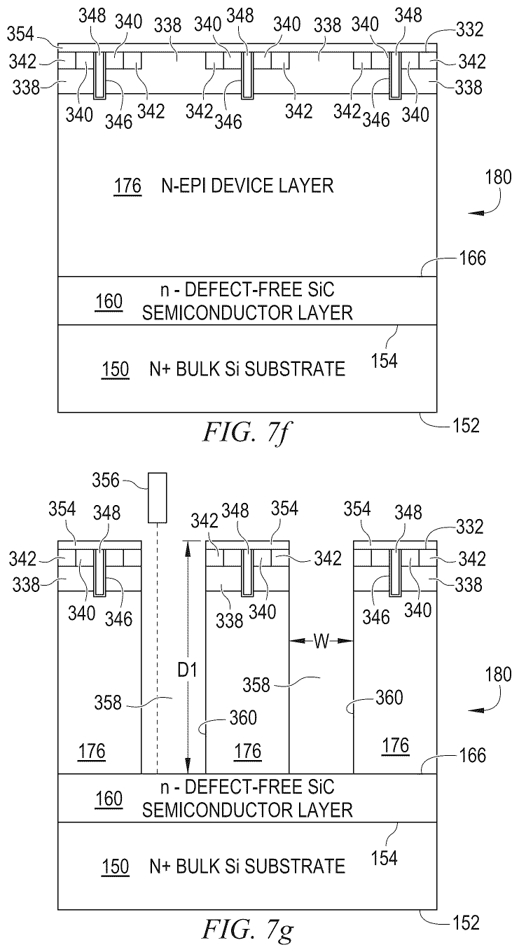

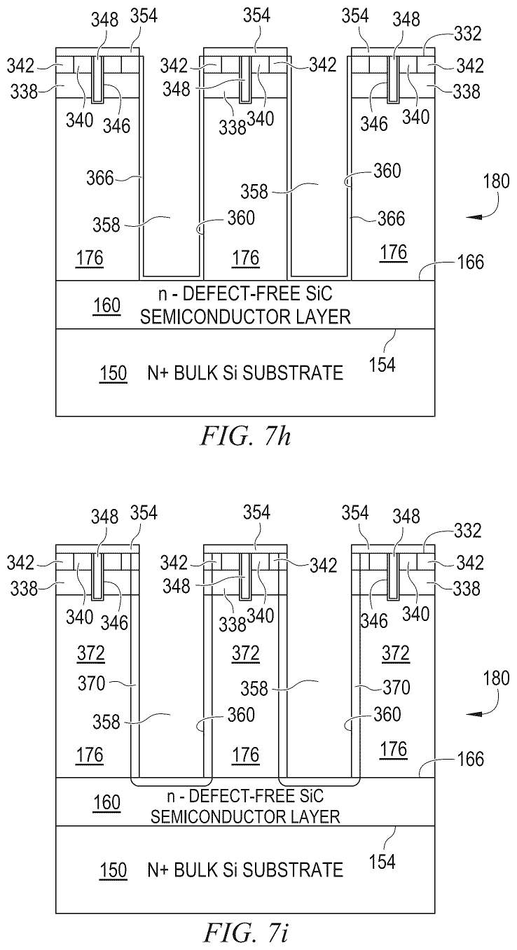

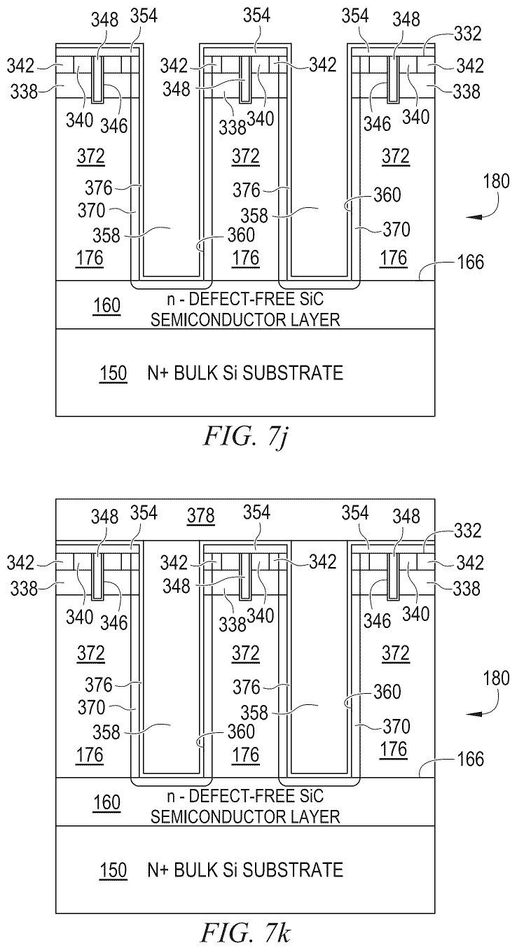

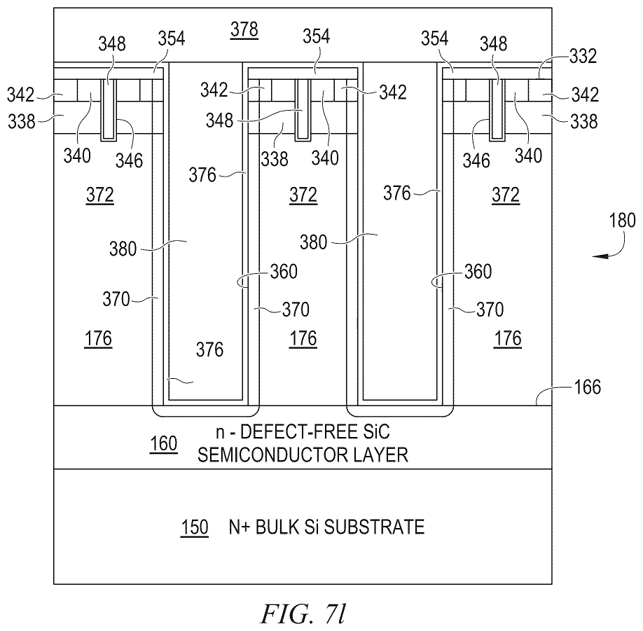

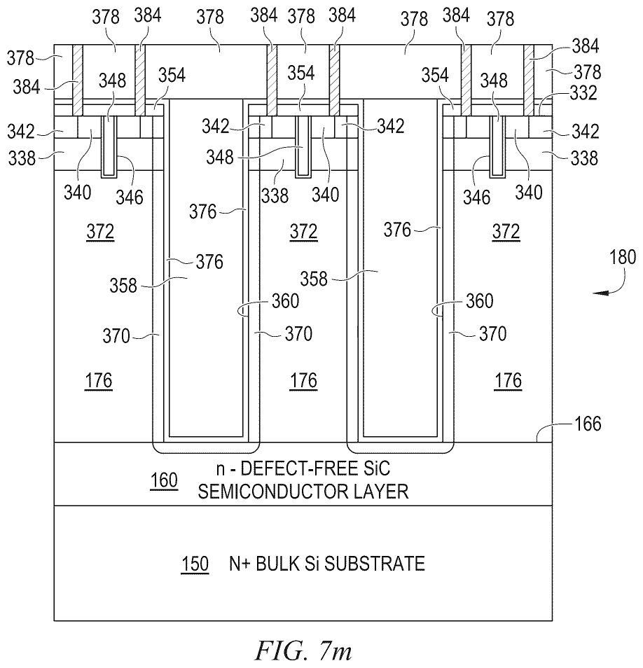

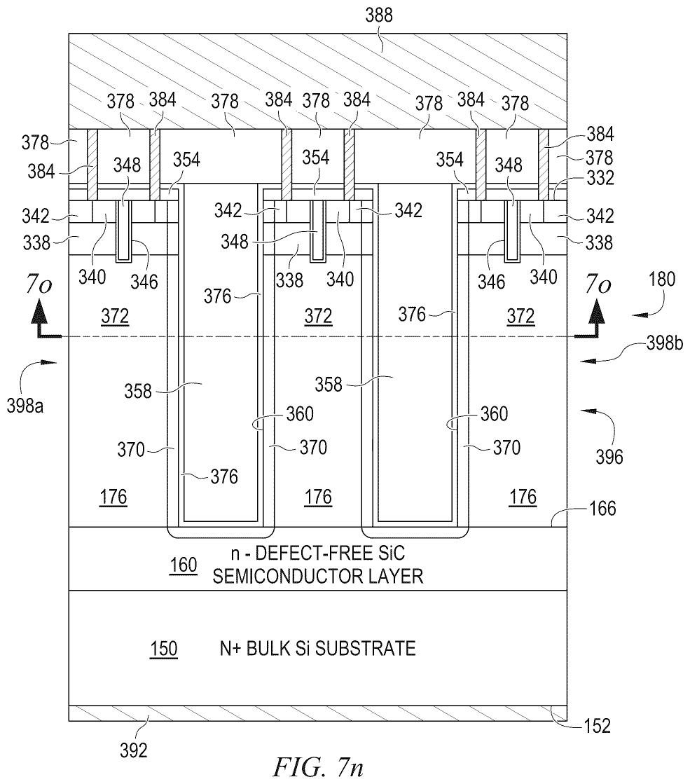

FIGS. 7a-7o illustrate a process of forming a multi-cell MEMS super-junction power MOSFET in engineered substrate 180 using vapor phase deposition to optimize for R_{DSON}. Elements or features having a similar function are assigned the same reference number. FIGS. 7a-7o represent a portion of engineered substrate 180 showing formation of two cells 398a-398b of the mSJMOS or MOSFET. In FIG. 7a, surface 332 of semiconductor layer 176 is implanted with a p-type impurity, such as B, Al, or Ga. The implant is performed at an energy level of about 30-200 KeV with a dose between 1e16 and 1e18 atoms/cm³, preferably 4e17 atoms/cm³. The p-type impurities are driven-in, at a temperature of 900° C. for 10-30 minutes, to form p body 338.

In FIG. 7b, surface 332 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form n+ source region 340.

Surface 332 is further implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form p+ contact 342.

In FIGS. 7c-7e, a portion of n+ source region 340, p body 338, and N-epitaxial (epi) device layer 176 is removed by an etching process or LDA using laser 343 to form trench 344 extending into the N-epi device layer. FIGS. 7d-7e show further detail of box 350 from FIG. 7c. An insulating layer 346 is formed over surface 347 within trench 344. Insulating layers, as described herein, can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 346 is an oxide layer. Polysilicon material 348 is formed over insulating layer 346 within trench 344. Polysilicon material 348 can be formed by PVD, CVD, screen printing, spin coating, spray coating, or other suitable deposition process. Polysilicon material 348 operates as a gate field plate. Note that n+ source region 340 and p+ contact 342 can be formed after trench 344, insulating layer 346, and polysilicon material 348.

In FIG. 7f, an insulating layer 354 is formed over surface 332. In FIG. 7g, a portion of insulating layer 354, p body 338, and N-epi device layer 176 is removed by DRIE or LDA using laser 356 to form trench 358. Trench 358 includes substantially vertical side surfaces 360. Trench 358 must extend at least to surface 166, and in most cases, will extend past surface 166 into semiconductor layer 160. In the case of trench etching, trenches 358 can be formed by DRIE with a width W of 1.0-2.0 or less μm, preferably 0.5 μm, and depth D1 of 1.5-2.0 μm for 30V and 100.0 μm for 1200V, depending on epi thickness, to extend past surface 166 into semiconductor layer 160. The width W of trench 358 is made small to decrease cell pitch and increase cell density. Depth D1 is greater for higher voltages and thicker epi. The DRIE is a highly anisotropic etch process used to create deep penetration, steep-sided holes, cavities, and trenches in wafers/substrates, typically with high aspect ratios. DRIE utilizes an ionized gas or plasma, such as SF₆, to remove material from N-epi device layer 176 and semiconductor layer 160. DRIE technology permits deeper trenches 358 with straighter side surfaces 360. To create deep anisotropic etching of silicon, the etch process switches between different plasma chemistries to provide fluorine-based etching of the silicon while protecting the side surface of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 358. Alternatively, trenches 358 can be formed by plasma etching, RIE, sputter etching, vapor phase etching, and chemical etching. A first mask (not shown) is typically formed over surface 332 to isolate trenches 358 during the etching process.

The side surfaces 360 of each trench 358 can be smoothed using an isotropic plasma etch and may be used to remove a thin layer of silicon, e.g., 100-1000 A from the trench sidewalls. Alternatively, a sacrificial thermal oxide or silicon dioxide layer can be grown on sidewall surfaces 360 of trenches 358. The sacrificial thermal oxide is then removed using an etch, such as a buffered oxide etch, or a diluted HF acid etch, or other wet chemistry followed by HF vapor phase fuming, to smooth the inner wall. Another sacrificial thermal oxide layer is again grown on side surfaces 360 of trenches 358. The sacrificial thermal oxide layer is again removed by wet chemistry followed by HF vapor phase fuming to smooth the inner wall. The process of repetitive growth of thermal oxide and removal continues multiple times until side surface 360 of trench 358 is smooth. By eliminating the scalloping from the DRIE etch and using the sacrificial thermal oxide layer followed by HF fuming or any oxide and silicon etches, side surface 360 can be smoothed to a tapered form. The use of the smoothing techniques can produce smooth trench surfaces with rounded corners while removing residual stress and unwanted contaminates.

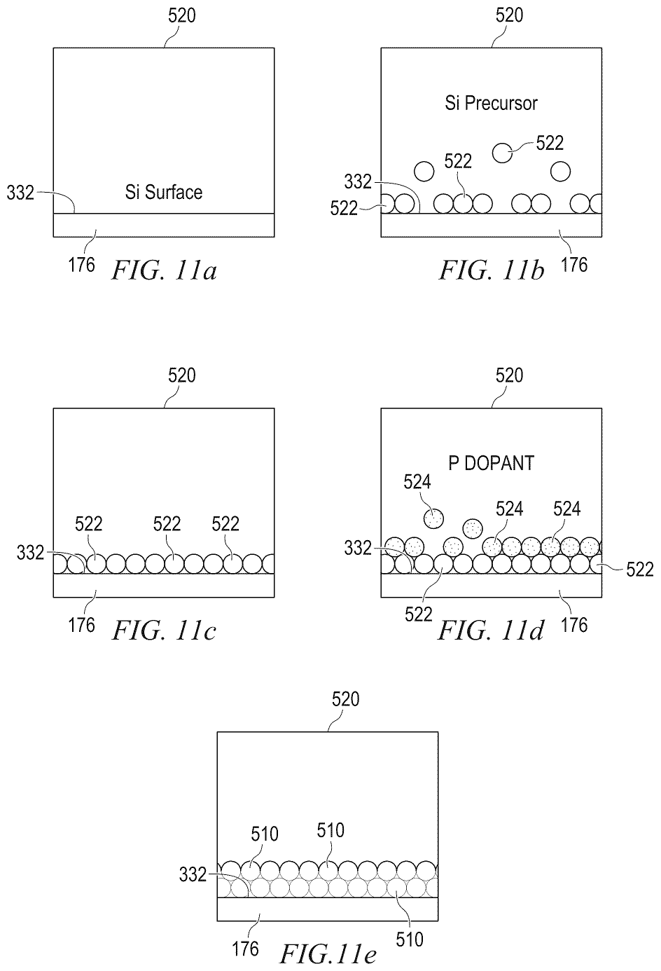

In FIG. 7h, thin film 366 is deposited on side surfaces 360 of trenches 358 using vapor phase deposition or plasma doping. Thin film 366 contains p-type dopant, such as boron, aluminum, or gallium impurities. In one embodiment, p type thin film 366 is deposited by low temperature CVD, PVD, and/or plasma enhanced chemical vapor deposition (PECVD). Alternatively, thin film 366 is formed by atomic level deposition (ALD). An example of ALD is shown in FIGS. 11a-11e.

In FIG. 7i, p type thin film 366 is then diffused into N− epi device layer 176 by application of pressure and heat, e.g., in a reaction chamber, in the range of 800-1000° C. at atmospheric pressure. Alternatively, the impurity atoms are transported from the vapor source onto surface 360 of trench 358 and simultaneously diffused into the semiconductor wafer, again by application of heat and pressure in a reaction chamber. The vapor source maintains a constant level of surface concentration during the entire diffusion period. The diffusion forms p regions or columns 370, leaving n regions or columns 372 from N-epi device layer 176 between the p columns. That is, forming p column 370 retains a portion of N-epi device layer 176 as n column 372 adjacent to the p column. In one embodiment, p columns 370 have a width of 0.1-0.5 μm. Accordingly, p columns 370 are formed by vapor phase deposition or plasma doping and diffusion, and n columns 372 are the remaining N-epi device layer 176 between the p columns. The vapor phase deposition or plasma doping and diffusion is particularly useful to form p columns 370, given the narrow trenches 358, e.g., 0.5 μm or less.

In FIG. 7j, insulating layer 376 is formed over insulating layer 354 and into trench 358 over a side surface of p columns 370. Insulating layer 376 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 376 typically, although not necessarily, covers the bottom of trench 358.

In FIG. 7k, insulating layer or material 378 is formed over insulating layer 376 and trench 358. Insulating material 378 can be SiO2, Si3N4, SiON, Ta2O5, Al2O3, polyimide, BCB, PBO, or other suitable insulating or dielectric material. In one embodiment, insulating layer 378 is formed using a MEMS layer transfer or layer bonding process to form a cap over trench 358, as it is not necessary to completely fill the trenches with insulating material. As part of MEMS layer transfer, insulating layer or cap 378, as an entire wafer, can be direct wafer bonded to insulating layer 376 to cover trench 358.

In another embodiment, insulating layer or material 380 is formed within trench 358, as shown in FIG. 7l. Insulating material 380 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 380 is formed using a MEMS layer transfer or layer bonding process, as described above.

Insulating material 378 can also be formed to cap trenches 358 using other techniques, such as LPCVD, TEOS, or other suitable oxide deposition process. Insulating material 378 can be polysilicon, re-crystallized polysilicon, single crystal silicon, or semi-insulating polycrystalline silicon (SIPOS). In one embodiment, insulating material 378 is SIPOS deposited into trenches 358 using SOG technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

Continuing from FIG. 7k, a portion of insulating layer 378 is removed by an etching process or LDA to form vias through the insulating layer extending to n+ source region 340, as in FIG. 7m. The vias are filled with conductive material to form conductive vias 384. Conductive vias 384 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive vias 384 make electrical contact with n+ source region 340. Conductive vias 384 are also used to generate an electric field for polysilicon gate material 348 (not shown).

In FIG. 7n, one or more electrically conductive layers 388 is formed over insulating layer 378 and make electrical connection to conductive vias 384. Conductive layer 188 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. An electrically conductive layer 392 is formed over surface 152 of substrate 150. Conductive layer 392 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 392 operates as back-side drain contact for mSJMOS or MOSFET 396.

FIG. 70 is a cross-sectional view of power MOSFET 396 from FIG. 7n illustrating n columns 372, p columns 370, insulating layer 376, and trench 358. In one embodiment, trench 358 has a width of 0.5 μm. The vapor phase deposition or plasma doping makes the formation of p columns 370 practical given the narrow trench width.

FIGS. 7m-7o illustrate two cells 398a and 398b of mSJMOS or MOSFET 396. MOSFET 396 is a multi-cell vertical power MOSFET having applications in DC-DC power converters, aerospace, and general purpose portable electrical devices. A top view of power MOSFET 396 showing multiple cells 398 arranged in an x by y array is shown in FIG. 8. Cells 398 can be rectangular, circular, or other geometric shape. For one cell, n+ source region 340 is the source of the power MOSFET, N-epi device layer 176 and N+ bulk Si substrate 150 operates as the drain, polysilicon material 348 and insulating layer 346 is the gate structure, and the portion of p body 338 vertically along polysilicon material 348 is the channel between the source and drain. P column 370 and n column 372 form the super-junction structure, with a charge balance between the p column and n column, to support a high breakdown voltage for the power MOSFET. MOSFET cells 398 are electrically connected in parallel to form a power MOSFET for high current carrying capacity. In one embodiment, power MOSFET cells 398 have a pitch of 5.0 μm and density of 4.0 million cells/cm². The ability to form p columns 370 to a depth of 100 μm, with a trench width of say 0.5 μm, relies on the vapor phase deposition and diffusion to extend the dopant to the requisite depths in a narrow trench. The structure of power MOSFET 396 has a feature size that is scalable to reduce cell size and provide a higher cell density, which increases the number of cells in the power MOSFET and reduces RDS_{ON} less than 5.0 mohms-cm2 at maximum drain current ID of 100.0 amperes. Power MOSFET 396 can be embodied on semiconductor die 104.

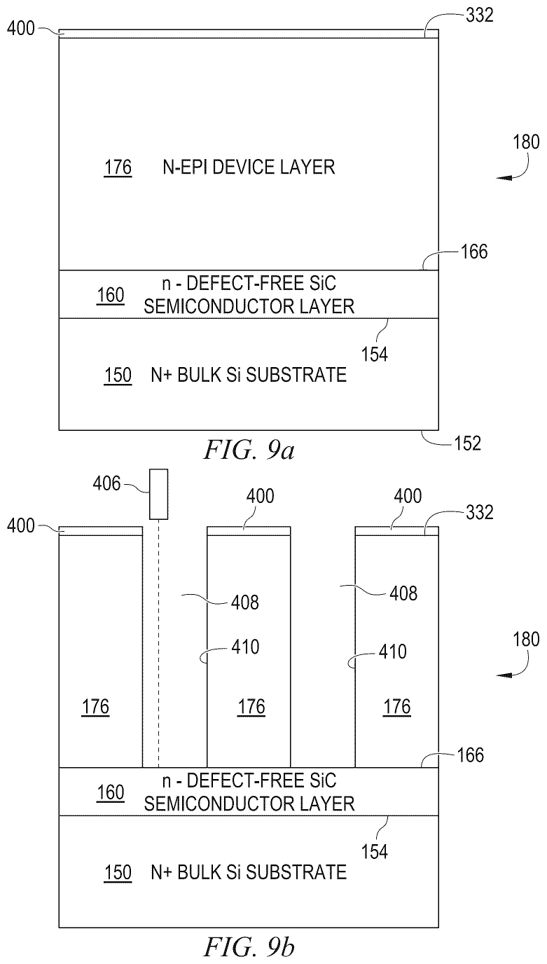

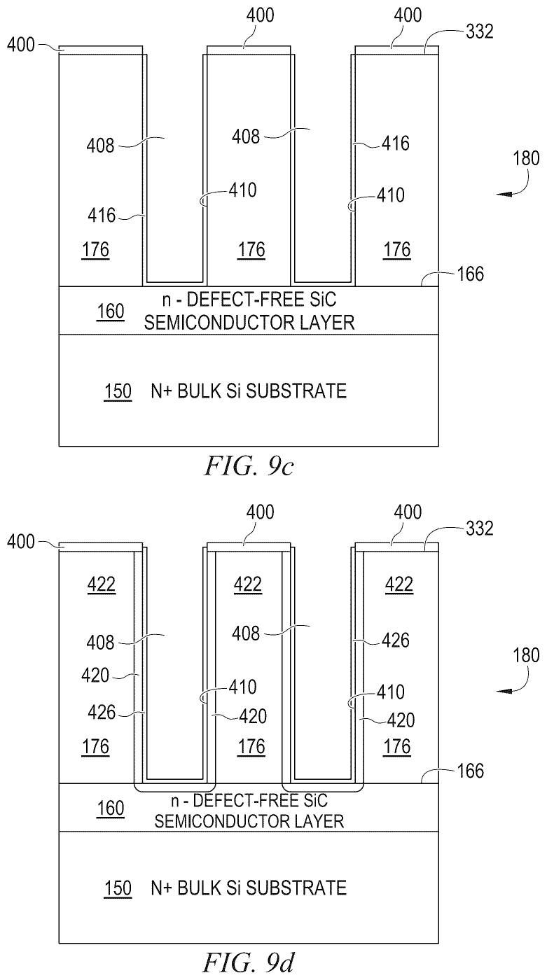

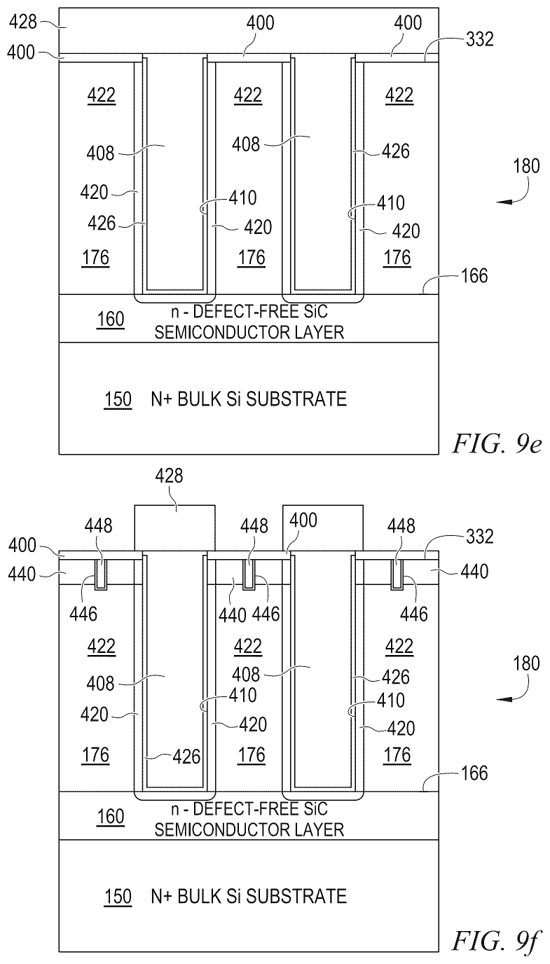

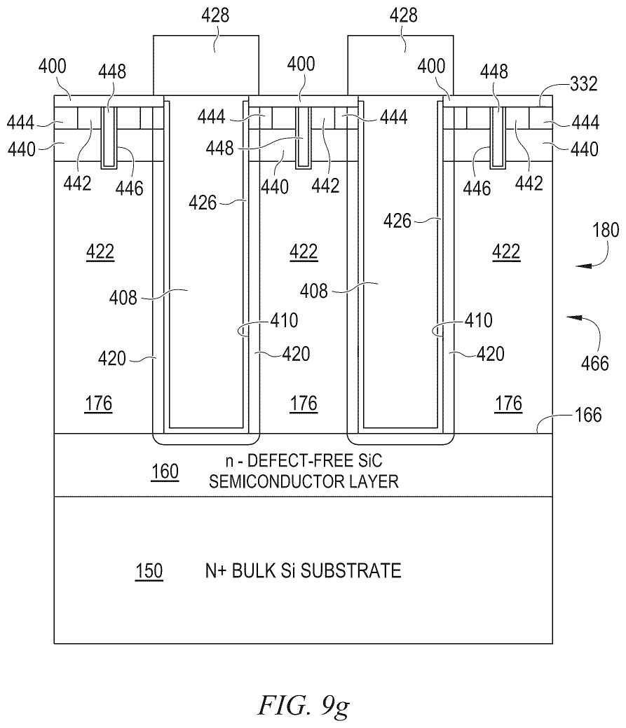

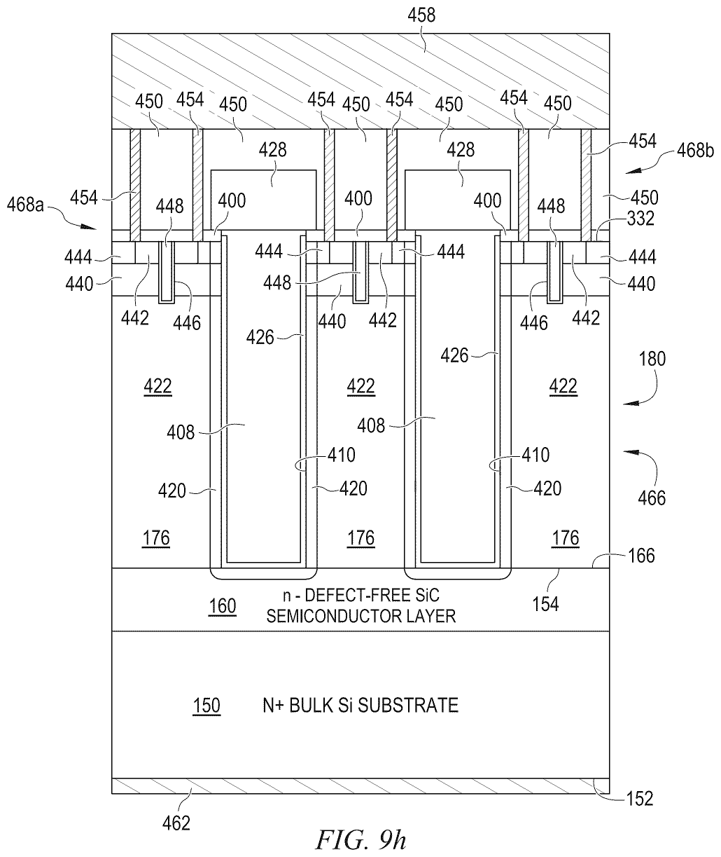

FIGS. 9a-9h illustrate another process of forming a multi-cell MEMS super-junction power MOSFET using vapor phase deposition to optimize for R_{DSON}. Elements or features having a similar function are assigned the same reference number. Continuing from FIG. 4n, insulating layer 400 is formed over surface 332 of N-epi device layer 176 of engineered substrate 180, as shown in FIG. 9a. Insulating layer 400 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation.

In FIG. 9b, a portion of insulating layer 400 and N-epi device layer 176 is removed by a DRIE or LDA using laser 406 to form trench 408. Trench 408 includes substantially vertical side surfaces 410. Trench 408 must extend at least to surface 166, and in most cases, will extend past surface 166 into semiconductor layer 160. In the case of trench etching, trenches 408 can be formed by DRIE, with a width and depth similar to trench 358, depending on epi thickness, to extend past surface 166 into semiconductor layer 160. The width of trench 408 is made small to decrease cell pitch and increase cell density. The depth of trench 408 is greater for higher voltages and thicker epi. The DRIE is a highly anisotropic etch process used to create deep penetration, steep-sided holes, cavities, and trenches in wafers/substrates, typically with high aspect ratios. DRIE utilizes an ionized gas or plasma, such as SF₆, to remove material from N-epi device layer 176 and semiconductor layer 160. DRIE technology permits deeper trenches 408 with straighter side surfaces 410. To create deep anisotropic etching of silicon, the etch process switches between different plasma chemistries to provide fluorine-based etching of the silicon while protecting the side surface of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 408. Alternatively, trenches 408 can be formed by plasma etching, RIE, sputter etching, vapor phase etching, and chemical etching. A first mask (not shown) is typically formed over surface 332 to isolate trenches 408 during the etching process.

The side surfaces 410 of each trench 408 can be smoothed using an isotropic plasma etch and may be used to remove a thin layer of silicon, e.g., 100-1000 A from the trench sidewalls. Alternatively, a sacrificial thermal oxide or silicon dioxide layer can be grown on sidewall surfaces 410 of trenches 408. The sacrificial thermal oxide is then removed using an etch, such as a buffered oxide etch, or a diluted HF acid etch, or other wet chemistry followed by HF vapor phase fuming, to smooth the inner wall. Another sacrificial thermal oxide layer is again grown on side surfaces 410 of trenches 408. The sacrificial thermal oxide layer is again removed by wet chemistry followed by HF vapor phase fuming to smooth the inner wall. The process of repetitive growth of thermal oxide and removal continues multiple times until side surface 410 of trench 408 is smooth. By eliminating the scalloping from the DRIE etch and using the sacrificial thermal oxide layer followed by HF fuming or any oxide and silicon etches, side surface 410 can be smoothed to a tapered form. The use of the smoothing technique can produce smooth trench surfaces with rounded corners while removing residual stress and unwanted contaminates.

In FIG. 9c, thin film 416 is deposited on side surfaces 410 of trenches 408 using low temperature vapor phase deposition or plasma doping. Alternatively, thin film 416 is formed by ALD. Thin film 416 contains p-type dopant, such as boron, aluminum, or gallium impurities. In one embodiment, p type thin film 416 is deposited by CVD, PVD, and/or PECVD. In FIG. 9d, p type thin film 416 is then diffused into N-epi device layer 176 by application of pressure and heat, e.g., in a reaction chamber, in the range of 800-1000° C. at atmospheric pressure. Alternatively, the impurity atoms are transported from the vapor source onto surface 410 of trench 408 and simultaneously diffused into the semiconductor wafer, again by application of heat and pressure in a reaction chamber. The vapor source maintains a constant level of surface concentration during the entire diffusion period. The diffusion forms p regions or columns 420, leaving n regions or columns 422 from N-epi device layer 176 between the p columns. That is, forming p column 420 retains a portion of N-epi device layer 176 as n column 422 adjacent to the p column. Accordingly, p columns 420 are formed by vapor phase deposition or plasma doping and diffusion, and n columns 422 are the remaining N-epi device layer 176 between the p columns. The vapor phase deposition or plasma doping and diffusion is particularly useful to form p columns 420, given the narrow trenches 408, e.g., 0.5 μm or less.

An insulating layer 426 is formed within trench 408 over side surface 410 of p columns 420. Insulating layer 426 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 426 typically, although not necessarily, covers the bottom of trench 408.

In FIG. 9e, insulating layer or material 428 is formed over insulating layer 400 and trench 408. Insulating material 428 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 428 is formed using a MEMS layer transfer or layer bonding process to form a cap over trench 408, as it is not necessary to completely fill the trenches with insulating material. Alternatively, insulating material 428 is formed within trench 408, similar to FIG. 7l. As part of MEMS layer transfer, insulating layer or cap 428, as an entire wafer, can be direct wafer bonded to insulating layer 400 to cover trench 408.

Insulating material 428 can also be formed to cap trenches 408 using other techniques, such as LPCVD, TEOS, or other suitable oxide deposition process. Insulating material 428 can be polysilicon, re-crystallized polysilicon, single crystal silicon, or SIPOS. In one embodiment, insulating material 428 is SIPOS deposited into trenches 408 using a SOG technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

In FIG. 9f, a portion of insulating material 428 is removed by an etching process or LDA to expose insulating layer 400 to allow formation of the p body, gate structure, and source region, while leaving insulating material 428 over trench 408. Surface 332 of N-epi device layer 176 is implanted with a p-type impurity, such as B, Al, or Ga, similar to FIG. 7a. The implant is performed at an energy level of about 30-200 KeV with a dose between 1e16 and 1e18 atoms/cm³, preferably 4e17 atoms/cm³. The p-type impurities are driven-in, at a temperature of 900° C. for 10-30 minutes, to form p body 440.

A portion of p body 440 and N-epi device layer 176 is removed by an etching process or LDA to form a trench extending into the N-epi device layer, similar to FIGS. 7d-7e. An insulating layer 446 is formed over the side surface within the trench. Insulating layer 446 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 446 is an oxide layer. Polysilicon material 448 is formed over insulating layer 446. Polysilicon material 448 can be formed by PVD, CVD, screen printing, spin coating, spray coating, or other suitable deposition process. Polysilicon material 448 operates as a gate field plate.

In FIG. 9g, surface 332 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form n+ source region 442, similar to FIG. 7b. Surface 332 is further implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form p+ contact 444.

In FIG. 9h, insulating layer 450 is formed over insulating layer 400 and insulating layer 428. Insulating layer 450 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 450 operates an ILD. A portion of insulating layer 450 is removed by an etching process or LDA to form vias through the insulating layer extending to n+ source region 442, similar to FIG. 7m. The vias are filled with conductive material to form conductive vias 454. Conductive vias 454 can be one or more layers of Al, Cu, Sn, Ni, Au, Ag, W, or other suitable electrically conductive material formed using patterning with PVD, CVD, sputtering, electrolytic plating, electroless plating process, or other suitable metal deposition process. Conductive vias 454 make electrical contact with n+ source region 442. Conductive vias 454 are also used to generate an electric field for polysilicon gate material 448 (not shown).

One or more electrically conductive layers 458 are formed over insulating layer 450 and make electrical connection to conductive vias 454, similar to FIG. 7n. Conductive layer 458 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. An electrically conductive layer 462 is formed over surface 152 of substrate 150. Conductive layer 462 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 462 operates as back-side drain contact for mSJMOS or MOSFET 466.

FIG. 9h illustrates two cells 468a and 468b of mSJMOS or MOSFET 466, similar to FIGS. 7m-7o. MOSFET 466 is a multi-cell vertical power MOSFET having applications in DC-DC power converters, aerospace, and general purpose portable electrical devices. A top view of power MOSFET 466 showing multiple cells 468 arranged in an x by y array would be similar to FIG. 8. For one cell, n+ source region 442 is the source of the power MOSFET, N-epi device layer 176 and N+ bulk Si substrate 150 operates as the drain, polysilicon material 448 and insulating layer 446 is the gate structure, and the portion of p body 440 vertically along polysilicon material 448 is the channel between the source and drain. P column 420 and n column 422 form the super-junction structure, with a charge balance between the p column and n column, to support a high breakdown voltage for the power MOSFET. MOSFET cells 468 are electrically connected in parallel to form a power MOSFET for high current carrying capacity. In one embodiment, power MOSFET cells 468 have a pitch of 5.0 μm and density of 4.0 million cells/cm². The ability to form p columns 420 to a depth of 100 μm, with a trench width of say 0.5 μm, relies on the vapor phase deposition and diffusion to extend the dopant to the requisite depths in a narrow trench. The structure of power MOSFET 466 has a feature size that is scalable to reduce cell size and provide a higher cell density, which increases the number of cells in the power MOSFET and reduces RDS_{ON} to 5.0 mohms-cm2 at maximum drain current ID of 100.0 amperes. Power MOSFET 466 can be embodied on semiconductor die 104.

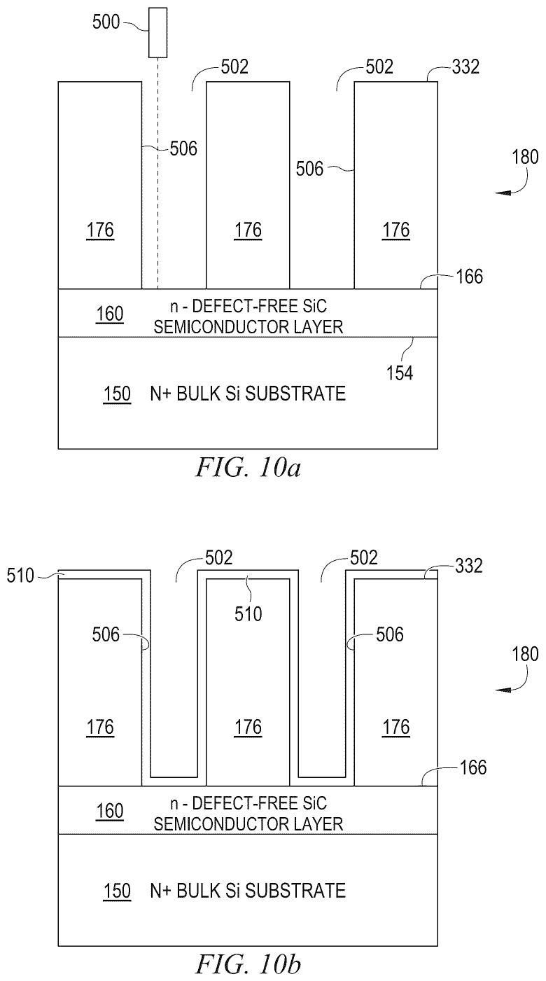

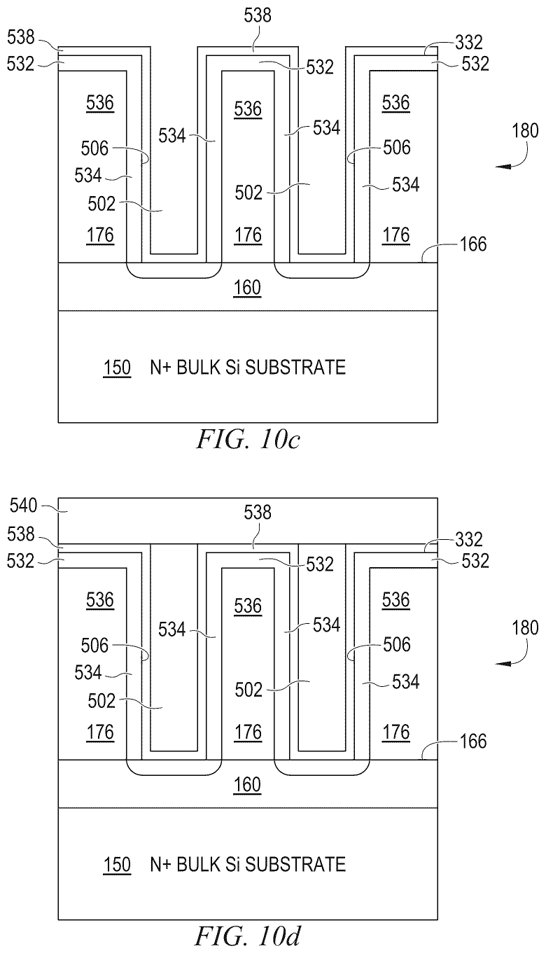

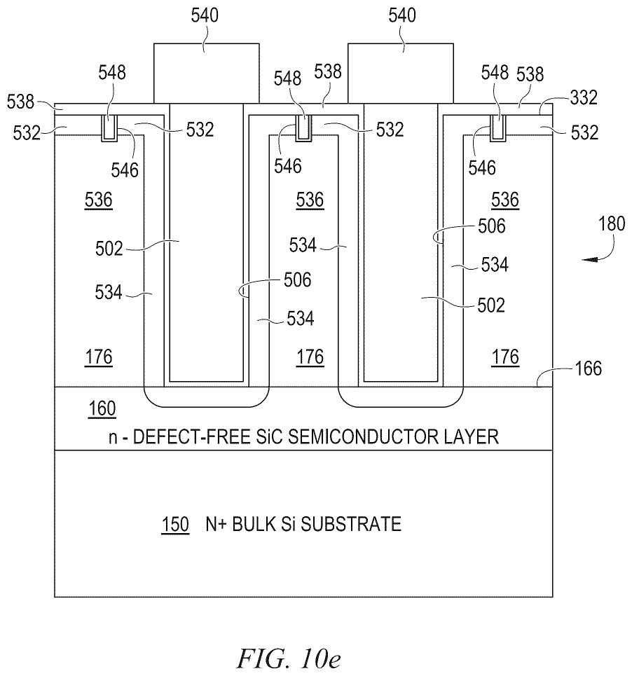

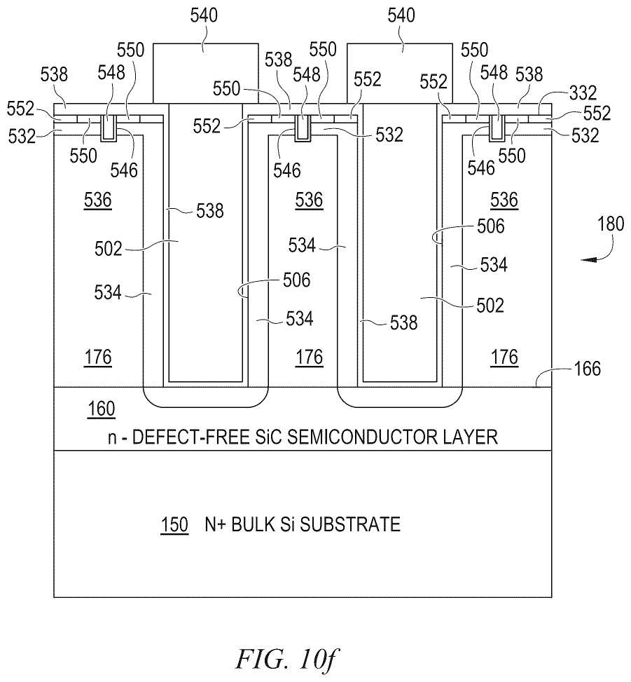

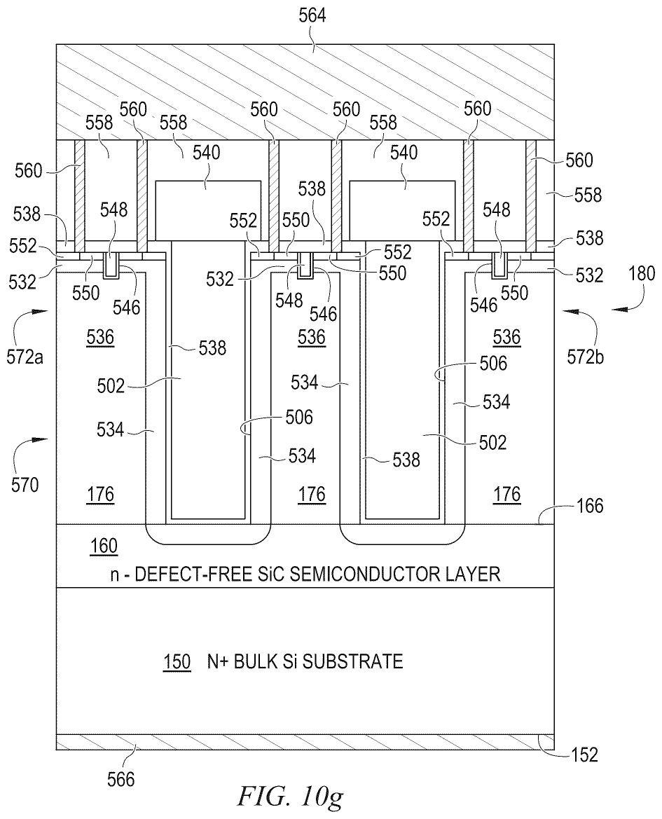

FIGS. 10a-10g illustrate another process of forming a multi-cell MEMS super-junction MOSFET using epi deposition or ALD to optimize for R_{DSON}. Elements or features having a similar function are assigned the same reference number. Continuing from FIG. 4n, a portion of N-epi device layer 176 is removed by a trench gate etching process or LDA using laser 500 to form trench 502, as shown in FIG. 10a. Trench 502 includes substantially vertical side surfaces 506. Trench 502 must extend at least to surface 166, and in most cases, will extend past surface 166 into semiconductor layer 160. In the case of trench etching, trenches 502 can be formed by DRIE, with a width and depth similar to trench 358, depending on epi thickness, to extend past surface 166 into semiconductor layer 160. The width of trench 502 is made small to decrease cell pitch and increase cell density. The depth of trench 502 is greater for higher voltages and thicker epi. The DRIE is a highly anisotropic etch process used to create deep penetration, steep-sided holes, cavities, and trenches in wafers/substrates, typically with high aspect ratios. DRIE utilizes an ionized gas or plasma, such as SF₆, to remove material from N-epi device layer 176 and semiconductor layer 160. DRIE technology permits deeper trenches 502 with straighter side surfaces 506. To create deep anisotropic etching of silicon, the etch process switches between different plasma chemistries to provide fluorine-based etching of the silicon while protecting the side surface of the growing feature with a fluorocarbon layer. A C₄F₈ plasma deposits a fluoropolymer passivation layer onto the mask and into the etched feature. A bias from the platen causes directional ion bombardment resulting in removal of the fluoropolymer from the base of the feature and the mask. The fluorine free radicals in the SF₆ plasma etch the exposed silicon at the base of the etch feature isotropically. The DRIE process repeats multiple times to achieve a vertical etch profile for trenches 502. Alternatively, trenches 502 can be formed by plasma etching, DRIE, sputter etching, vapor phase etching, and chemical etching. A first mask (not shown) is typically formed over surface 332 to isolate trenches 502 during the etching process.

The side surfaces 506 of each trench 502 can be smoothed using an isotropic plasma etch and may be used to remove a thin layer of silicon, e.g., 100-1000 A from the trench sidewalls. Alternatively, a sacrificial thermal oxide or silicon dioxide layer can be grown on sidewall surfaces 506 of trenches 502. The sacrificial thermal oxide is then removed using an etch, such as a buffered oxide etch, or a diluted HF acid etch, or other wet chemistry followed by HF vapor phase fuming, to smooth the inner wall. Another sacrificial thermal oxide layer is again grown on side surfaces 506 of trenches 502. The sacrificial thermal oxide layer is again removed by wet chemistry followed by HF vapor phase fuming to smooth the inner wall. The process of repetitive growth of thermal oxide and removal continues multiple times until side surface 506 of trench 502 is smooth. By eliminating the scalloping from the DRIE etch and using the sacrificial thermal oxide layer followed by HF fuming or any oxide and silicon etches, side surface 506 can be smoothed to a tapered form. The use of the smoothing technique can produce smooth trench surfaces with rounded corners while removing residual stress and unwanted contaminates.

In FIG. 10b, epi layer 510 is epitaxially grown on surface 332 and side surfaces 506 of trenches 502. Alternatively, epi layer 510 is formed by ALD. FIG. 11a shows a semiconductor surface, such as surface 332 and 506, in reaction chamber 520. In FIG. 11b, precursors 522 flow into reaction chamber 520 in a gaseous state. FIG. 11c shows precursors 522 coating or absorbing into the target surface, i.e., surfaces 332 and 506. In FIG. 11d, a second gas with p type dopants 524 is introduced into reaction chamber 520 to react with precursors 522. FIG. 11e shows the resulting p type epi layer 510 formed on surfaces 332 and 506. ALD offers exceptional conformality on high-aspect ratio structures, thickness control at the angstrom level, and tunable film composition. Either by epitaxial growth or ALD, epi layer 510 contains p-type dopant, such as boron, aluminum, or gallium impurities.

In FIG. 10c, p type epi layer 510 is diffused into N-epi device layer 176 by application of pressure and heat, e.g., in a reaction chamber, in the range of 800-1000° C. at atmospheric pressure. Alternatively, the impurity atoms are transported from the vapor source onto side surface 506 of trench 502 and simultaneously diffused into the semiconductor wafer, again by application of heat and pressure in a reaction chamber. The vapor source maintains a constant level of surface concentration during the entire diffusion period. The diffusion of p type epi layer 510 into surface 332 forms p body regions 532. The diffusion of p type epi layer 510 into side surface 506 of trench 502 forms p regions or columns 534, leaving n regions or columns 536 from N-epi device layer 176 between the p columns. That is, forming p column 534 retains a portion of N-epi device layer 176 as n column 536 adjacent to the p column. Accordingly, p columns 534 are formed by epi growth and diffusion and n columns 536 are the remaining N-epi device layer 176 between the p columns. The epi layer deposition or ALD and diffusion is particularly useful to form p columns 534, given the narrow trenches 502, e.g., 0.5 μm or less.

An insulating layer 538 is formed over surface 332 and within trench 502 over side surface 506 of p columns 534. Insulating layer 538 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 538 typically, although not necessarily, covers the bottom of trench 502.

In FIG. 10d, insulating layer or material 540 is formed over insulating layer 538 and trench 502. Insulating material 540 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 540 is formed using a MEMS layer transfer or layer bonding process to form a cap over trench 502, as it is not necessary to completely fill the trenches with insulating material. Alternatively, insulating material 540 is formed within trench 502, similar to FIG. 7l. As part of MEMS layer transfer, insulating layer or cap 540, as an entire wafer, can be direct wafer bonded to insulating layer 538 to cover trench 502.

Insulating material 540 can also be formed to cap trenches 502 using other techniques, such as LPCVD, TEOS, or other suitable oxide deposition process. Insulating material 540 can be polysilicon, re-crystallized polysilicon, single crystal silicon, or SIPOS. In one embodiment, insulating material 540 is SIPOS deposited into trenches 502 using a SOG technique. The amount of oxygen content in the SIPOS is chosen to be between 2% and 80% to improve the electrical characteristics of the active region. Increasing the amount of oxygen content is desirable for electrical characteristics, but varying the oxygen content also results in altered material properties. Higher oxygen content SIPOS thermally expands and contracts differently from the surrounding silicon which may lead to undesirable fracturing or cracking, especially near the interface of differing materials. Accordingly, the oxygen content of the SIPOS is optimally selected to achieve the most desirable electrical characteristics without an undesirable impact on mechanical properties.

In FIG. 10e, a portion of insulating material 540 is removed by an etching process or LDA to expose insulating layer 538 to allow formation of the gate structure and source region, while leaving insulating material 540 over trench 502. A portion of p body 532 and N-epi device layer 176 is removed by an etching process or LDA to form a trench extending into the N-epi device layer, similar to FIGS. 7d-7e. An insulating layer 546 is formed over the side surface within the trench. Insulating layer 546 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. In one embodiment, insulating layer 546 is an oxide layer. Polysilicon material 548 is formed over insulating layer 546. Polysilicon material 548 can be formed by PVD, CVD, screen printing, spin coating, spray coating, or other suitable deposition process. Polysilicon material 548 operates as a gate field plate.

In FIG. 10f, surface 332 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form n+ source region 550, similar to FIG. 7b. Surface 332 is further implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form p+ contact 552.

In FIG. 10g, insulating layer 558 is formed over insulating layer 538 and insulating layer 540. Insulating layer 558 can be SiO2, Si3N4, SiON, Ta2O5, Al2O3, polyimide, BCB, PBO, or other suitable insulating or dielectric material formed using PVD, CVD, screen printing, spin coating, spray coating, sintering, or thermal oxidation. Insulating layer 558 operates an ILD. Insulating layer 558 can extend over insulating layer 540. A portion of insulating layer 558 is removed by an etching process or LDA to form vias through the insulating layer extending to n+ source region 550, similar to FIG. 7m. The vias are filled with conductive material to form conductive vias 560. Conductive vias 560 can be one or more layers of Al, Cu, Sn, Ni, Au, Ag, W, or other suitable electrically conductive material formed using patterning with PVD, CVD, sputtering, electrolytic plating, electroless plating process, or other suitable metal deposition process. Conductive vias 560 make electrical contact with n+ source region 550. Conductive vias 560 are also used to generate an electric field for polysilicon gate material 548 (not shown).

One or more electrically conductive layers 564 are formed over insulating layer 558 and make electrical connection to conductive vias 560, similar to FIG. 7n. Conductive layer 564 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. An electrically conductive layer 566 is formed over surface 152 of semiconductor layer 160. Conductive layer 566 can be one or more layers of Al, Cu, Sn, Ni, Au, Ag, or other suitable electrically conductive material formed using patterning with PVD, CVD, sputtering, electrolytic plating, electroless plating process, or other suitable metal deposition process. Conductive layer 566 operates as back-side drain contact for mSJMOS or MOSFET 570.

FIG. 10g illustrates two cells 572a and 572b of mSJMOS or MOSFET 570, similar to FIGS. 7m-7o. MOSFET 570 is a multi-cell vertical power MOSFET having applications in DC-DC power converters, aerospace, and general purpose portable electrical devices. A top view of power MOSFET 570 showing multiple cells 572 arranged in an x by y array would be similar to FIG. 8. For one cell, n+ source region 550 is the source of the power MOSFET, N-epi device layer 176 and N+ bulk Si substrate 150 operates as the drain, polysilicon material 548 and insulating layer 546 is the gate structure, and the portion of p body 532 vertically along polysilicon material 548 is the channel between the source and drain. P column 534 and n column 536 form the super-junction structure, with a charge balance between the p column and n column, to support a high breakdown voltage for the power MOSFET. Power MOSFET cells 570 are electrically connected in parallel to form a power MOSFET for high current carrying capacity. In one embodiment, power MOSFET cells 570 have a pitch of 5.0 μm and density of 4.0 million cells/cm². The ability to form p columns 534 to a depth of 100 μm, with a trench width of say 0.5 μm, relies on the epi doping and diffusion to extend the dopant to the requisite depths in a narrow trench. The structure of power MOSFET 570 has a feature size that is scalable to reduce cell size and provide a higher cell density, which increases the number of cells in the power MOSFET and reduces RDS_{ON} to 5.0 mohms-cm2 at maximum drain current ID of 100.0 amperes. Power MOSFET 570 can be embodied on semiconductor die 104.

The high-breakdown voltage characteristics of FIGS. 5a-5k, 6, 7a-7o, 9a-9h, and 10a-10g can be applied to an IGBT, cluster trench insulated gate bipolar transistor (CTIGBT), thyristor, diode, and other MOS gated devices and electrical components. The semiconductor devices, as described in US publication 2023/0154976, US publication 2023/0154977, US publication 2023/0065348, US publication 2023/0067511, US publication 2023/0064236, US publication 2023/0061775, US publication 2023/01061047, and US publication 2023/0060866, and incorporated herein by reference, can be formed in engineered substrate 180 or 190.

In summary, engineered substrate 180, as described herein, provides a foundation for a variety of semiconductor devices. In particular, the inversion of the assembly from FIG. 4h and removal of structured substrate 120 and the high defect density portion of semiconductor layer 140 is referred to as providing a switch-back defect-free substrate. Semiconductor layers 160 and 176 require no high temperature processing, such as anneal, and associated high cost equipment. Thus, the innovative engineered substrate 180 can be manufactured in a mature mode CMOS process. The MEMS direct wafer bonding processes include plasma activated DWB of a substantially defect-free N-3C—SiC/N—Si heteroepitaxy film to a silicon substrate to create the advanced engineered substrate 180 that becomes the starting material for CMOS processing of, for example, a 1200V SJMOS embedded drain SiC high voltage power MOSFET. The switch-back process provides for low defect density on 3c-SiC or SiC epi. In addition, the Si/3C—SiC/Si structure of engineered substrate 180 is useful for radiation hardness. 3C—SiC layer provides a buffering effect over Si when a high energy particle impacts the device.

Power MOSFETs 280, 320, 396, 466, and 570 are each designed for high-breakdown voltage, high reliability, lightweight, low voltage, e.g., 3.3 VDC, and low R_{DSON} applications, e.g., 90 milliohms at ID=40 A, such as DC to DC converters, aerospace, and high-performance computing. The semiconductor structure between surface 166 and surface 238 substantially represents a super-junction semiconductor device. The super-junction cells like 282, 284 account for the total breakdown voltage capability. The 1200 v breakdown capacity is useful of efficient power distribution systems in aerospace applications, where the above advantages are particularly important. Near defect-free SiC semiconductor layer 160 together with Si device layer 176 provides the desired 1200 v.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
forming a first semiconductor layer over the first substrate;
disposing a second substrate over a surface of the first semiconductor layer opposite the first substrate;
removing the first substrate and a portion of the first semiconductor layer to reduce defects in the first semiconductor layer;
forming a second semiconductor layer over a remaining portion of the first semiconductor layer;
disposing a third semiconductor layer over the second semiconductor layer; and
forming an electrical component within the third semiconductor layer.

2. The method of claim 1, wherein the first semiconductor layer and second semiconductor layer each include silicon carbide or cubic silicon carbide.

3. The method of claim 1, wherein the third semiconductor layer includes silicon.

4. The method of claim 1, further including:
providing a third substrate;
disposing the third semiconductor layer over the third substrate; and
disposing the third semiconductor layer over the second semiconductor layer with the third semiconductor layer disposed over the third substrate.

5. The method of claim 1, further including disposing the third semiconductor layer over the second semiconductor layer by direct wafer bonding.

6. The method of claim 1, wherein the electrical component is selected from a group consisting of a power MOSFET, insulated gate bipolar transistor, cluster trench insulated gate bipolar transistor, diode, and thyristor.

7. A method of making a semiconductor device, comprising:
providing a first substrate;
forming a first semiconductor layer over the first substrate;
disposing a second substrate over a surface of the first semiconductor layer opposite the first substrate;
removing the first substrate and a portion of the first semiconductor layer;
forming a second semiconductor layer over a remaining portion of the first semiconductor layer, wherein the second semiconductor layer is substantially defect-free; and
disposing a third semiconductor layer over the second semiconductor layer to provide an engineered substrate.

8. The method of claim 7, wherein the first semiconductor layer and second semiconductor layer each include silicon carbide or cubic silicon carbide.

9. The method of claim 7, wherein the third semiconductor layer includes silicon.

10. The method of claim 7, further including:
providing a third substrate;
disposing the third semiconductor layer over the third substrate; and
disposing the third semiconductor layer over the second semiconductor layer with the third semiconductor layer disposed over the third substrate.

11. The method of claim 7, further including disposing the third semiconductor layer over the second semiconductor layer by direct wafer bonding.

12. The method of claim 7, further including forming an electrical component within the third semiconductor layer.

13. The method of claim 12, wherein the electrical component is selected from a group consisting of a power MOSFET, insulated gate bipolar transistor, cluster trench insulated gate bipolar transistor, diode, and thyristor.

14. A semiconductor device, comprising:
a first semiconductor layer;
a first substrate disposed over a surface of the first semiconductor layer;
a second semiconductor layer formed over the first semiconductor layer, wherein the second semiconductor layer is substantially defect-free; and
a third semiconductor layer disposed over the second semiconductor layer to provide an engineered substrate.

15. The semiconductor device of claim 14, wherein the first semiconductor layer and second semiconductor layer each include silicon carbide or cubic silicon carbide.

16. The semiconductor device of claim 14, wherein the third semiconductor layer includes silicon.

17. The semiconductor device of claim 14, further including a second substrate, wherein the third semiconductor layer is disposed over the second substrate and the third semiconductor layer is disposed over the second semiconductor layer with the third semiconductor layer disposed over the second substrate.

18. The semiconductor device of claim 14, wherein the third semiconductor layer is disposed over the second semiconductor layer by direct wafer bonding.

19. The semiconductor device of claim 14, further including an electrical component formed within the third semiconductor layer.

20. The semiconductor device of claim 19, wherein the electrical component is selected from a group consisting of a power MOSFET, insulated gate bipolar transistor, cluster trench insulated gate bipolar transistor, diode, and thyristor.
